(19) United States
(12) Patent Application Publication
(10) Pub. No.: US 2026/0362800 A1
(43) Pub. Date: Nov. 12, 2026

(54) INTEGRATED CIRCUIT DEVICE INCLUDING VERTICALLY STACKED FIELD EFFECT TRANSISTORS

(71) Applicant: Samsung Electronics Co., Ltd., Suwon-si (KR)

(72) Inventors: Sangwoo Han, Suwon-si (KR); Jaehyun Park, Suwon-si (KR); Juhun Park, Suwon-si (KR); Jinchan Yun, Suwon-si (KR)

(73) Assignee: Samsung Electronics Co., Ltd., Suwon-si (KR)

(21) Appl. No.: 19/426,537

(22) Filed: Dec. 19, 2025

(30) Foreign Application Priority Data
May 8, 2025 (KR) 10-2025-0059901

(51) Int. Cl. H10D 84/85; H10D 84/01

(52) U.S. Cl. CPC H10D 84/854; H10D 84/0167; H10D 84/017; H10D 84/0186; H10D 84/851

(57) ABSTRACT

An integrated circuit device includes a first source/drain region including a first-conductivity-type semiconductor material, a second source/drain region overlapping the first source/drain region in a vertical direction, spaced apart from the first source/drain region in the vertical direction, and including a second-conductivity-type semiconductor material, a through contact structure passing through the second source/drain region in the vertical direction, the through contact structure connected to each of the first source/drain region and the second source/drain region, a first metal silicide film between the first source/drain region and the through contact structure, and a second metal silicide film between the second source/drain region and the through contact structure. The first metal silicide film and the second metal silicide film include different materials from one another.

### CROSS-REFERENCE TO RELATED APPLICATIONS

This present application claims priority to and the benefit under 35 U.S.C. § 119(a)-(d) of Korean Patent Application No. 10-2025-0059901, filed on May 8, 2025, in the Korean Intellectual Property Office, the entire disclosure of which is incorporated herein by reference.

### FIELD

The disclosed concepts relate to an integrated circuit (IC) device, and more particularly, to an IC device including field-effect transistors (FETs) that are vertically stacked.

### BACKGROUND

As the downscaling of IC devices has rapidly progressed, there has been a limit to increasing the number of transistors per unit area in a two-dimensional circuit in which p-channel metal-oxide semiconductor (PMOS) and n-channel metal-oxide semiconductor (NMOS) field-effect transistors (FETs) having gate all around (GAA) structures are arranged laterally. Accordingly, new techniques are needed to further increase integration density by further increasing the number of transistors per unit area while improving the electrical performance of each of the PMOS FETs and the NMOS FETs.

### SUMMARY

The disclosed concepts provide an integrated circuit (IC) device having a device region with a reduced area due to downscaling, and the IC device may have a structure that may improve the electrical performance of each of a PMOS field-effect transistor (FET) and an NMOS FET and further increase integration density by minimizing an area required for forming wirings.

According to aspects of the disclosed concepts, there is provided an IC device including a first source/drain region including a first-conductivity-type semiconductor material, a second source/drain region overlapping the first source/drain region in a vertical direction and spaced apart from the first source/drain region in the vertical direction, and the second source/drain region including a second-conductivity-type semiconductor material, a through contact structure passing through the second source/drain region in the vertical direction and connected to each of the first source/drain region and the second source/drain region, a first metal silicide film between the first source/drain region and the through contact structure, and a second metal silicide film between the second source/drain region and the through contact structure, wherein the first metal silicide film and the second metal silicide film include different materials from each other.

According to aspects of the disclosed concepts, there is provided an IC device including at least one first nanosheet and at least one second nanosheet overlapping one another in a vertical direction and spaced apart from one another in the vertical direction, a pair of first source/drain regions spaced apart in a first lateral direction from one another with the at least one first nanosheet therebetween, the pair of first source/drain regions being each in contact with the at least one first nanosheet and including a first-conductivity-type semiconductor material, a pair of second source/drain regions spaced apart in the first lateral direction from one another with the at least one second nanosheet therebetween, the pair of second source/drain regions being each in contact with the at least one second nanosheet and spaced apart from the first source/drain region in the vertical direction, and the pair of second source/drain regions including a second-conductivity-type semiconductor material, a gate line between the pair of first source/drain regions and between the pair of second source/drain regions, the gate line surrounding the at least one first nanosheet and the at least one second nanosheet, a through contact structure passing through a first one of the pair of second source/drain regions in the vertical direction, a first metal silicide film between a first one of the pair of first source/drain region and the through contact structure, and a second metal silicide film between the first one of the pair of second source/drain regions and the through contact structure, wherein the first metal silicide film and the second metal silicide film include different materials from one another.

According to aspects of the disclosed concepts, there is provided an IC device including a first source/drain region including a p-type semiconductor material, a second source/drain region overlapping the first source/drain region in a vertical direction and spaced apart from the first source/drain region in the vertical direction, the second source/drain region including an n-type semiconductor material, a through contact structure passing through the second source/drain region in the vertical direction, a first metal silicide film between the first source/drain region and the through contact structure, and a second metal silicide film between the second source/drain region and the through contact structure, the second metal silicide film including a material different from a material that the first metal silicide film includes, wherein the through contact structure includes an upper contact plug passing through the second source/drain region in the vertical direction, a conductive contact liner between the second source/drain region and the upper contact plug, the conductive contact liner surrounding a sidewall and a bottom surface of the upper contact plug, and a lower contact plug spaced apart in the vertical direction from the upper contact plug with the conductive contact liner therebetween, the lower contact plug including a portion surrounded by the first source/drain region, wherein the upper contact plug, the conductive contact liner, and the lower contact plug include different metals selected from molybdenum (Mo), zirconium (Zr), tungsten (W), copper (Cu), cobalt (Co), ruthenium (Ru), manganese (Mn), titanium (Ti), tantalum (Ta), and aluminum (Al).

According to aspects of the disclosed concepts, there is provided a method of manufacturing an IC device. The method includes forming a fin-type active region on a substrate. A first nanosheet and a second nanosheet are formed on the fin-type active region. The second nanosheet is spaced apart from the first nanosheet. A first source/drain region is formed on the fin-type active region. The first source/drain region is in contact with the first nanosheet and includes a first-conductivity-type semiconductor material. An insulating pattern is formed on the first source/drain region. A second source/drain region is spaced apart in the vertical direction from the first source/drain region with the insulating pattern therebetween. The second source/drain region is in contact with the second nanosheet and includes a second-conductivity-type semiconductor material. An insulating structure is formed to cover the second source/drain region. A gate line is formed to surround the first nanosheet and the second nanosheet. A through contact structure, a first metal silicide film, and a second metal silicide film are formed. The through contact structure is configured to pass through the second source/drain region and the insulating structure in the vertical direction and be connected to each of the first source/drain region and the second source/drain region. The first metal silicide film is between the first source/drain region and the through contact structure. The second metal silicide film is between the second source/drain region and the through contact structure and includes a material different from a constituent material of the first metal silicide film.

In embodiments, the formation of the through contact structure, the first metal silicide film, and the second metal silicide film may include forming a through hole to pass through the second source/drain region and the insulating structure in the vertical direction and pass through a portion of the first source/drain region in the vertical direction, forming the first metal silicide film, which is in contact with the first source/drain region exposed by the through hole, and a lower contact plug located on the first metal silicide film to fill a portion of the through hole, which is surrounded by a first source/drain region, and forming a conductive contact liner, which is in contact with the lower contact plug and the second source/drain region and conformally covers an inner surface of the through hole on the lower contact plug, and the second metal silicide film located between the conductive contact liner and the second source/drain region, and forming an upper contact plug filling the through hole on the conductive contact liner.

In embodiments, the lower contact plug, the conductive contact liner, and the upper contact plug may include different metals from one another.

In embodiments, the formation of the through hole may include dividing the second source/drain region into a first local portion and a second local portion, which are spaced apart in a first lateral direction from one another with the through hole therebetween.

In embodiments, the formation of the through hole may include forming a first through hole to pass through the insulating structure in the vertical direction and expose the second source/drain region, forming an insulating liner to conformally cover inner surfaces of the first through hole, forming a second through hole having an inner sidewall exposing the second source/drain region by etching a portion of the insulating liner and a portion of the second source/drain region through the first through hole, forming a capping liner to conformally cover the inner sidewall of the second through hole, and etching a portion of the first source/drain region by using the capping liner as an etch mask.

In embodiments, after the upper contact plug is formed, the method may further include forming a back-side metal silicide film apart from the through contact structure in the vertical direction to be in contact with a back-side surface of the first source/drain region and forming a back-side contact apart in the vertical direction from the first source/drain region with the back-side metal silicide film therebetween to be in contact with the back-side metal silicide film.

In embodiments, the lower contact plug may include molybdenum (Mo), the conductive contact liner may include zirconium (Zr), the upper contact plug may include tungsten (W), the first metal silicide film may include Mo silicide, and the second metal silicide film may include Zr silicide.

In embodiments, the method may further include forming a place holder in the fin-type active region before the first source/drain region is formed, removing the place holder to expose the back-side surface of the first source/drain region after the through contact structure, the first metal silicide film, and the second metal silicide film are formed, forming a back-side metal silicide film in contact with the back-side surface of the first source/drain region after the place holder is removed, and forming a back-side contact apart in the vertical direction from the first source/drain region with the back-side metal silicide film therebetween to be in contact with the back-side metal silicide film.

In embodiments, the method may further include forming a gate cut hole by removing a portion of the gate line and forming a gate cut insulating structure filling the gate cut hole after the gate line is formed and before the through contact structure, the first metal silicide film, and the second metal silicide film are formed, forming a plurality of via power rails to pass through the gate cut insulating structure in the vertical direction, and forming a back-side contact to be connected to the first source/drain region from a back of the first source/drain region after the through contact structure, the first metal silicide film, and the second metal silicide film are formed.

In embodiments, the first source/drain region may include a p-type semiconductor material, and the second source/drain region may include an n-type semiconductor material.

### BRIEF DESCRIPTION OF THE DRAWINGS

Embodiments will be more clearly understood from the following detailed description taken in conjunction with the accompanying drawings in which:

FIGS. 1A and 1B are each a plan layout diagram of an integrated circuit (IC) device according to embodiments;

FIG. 2A is a cross-sectional view taken along line X1-X1′ of FIGS. 1A and 1B;

FIG. 2B is a cross-sectional view taken along line Y1-Y1′ of FIGS. 1A and 1B;

FIG. 2C is a cross-sectional view taken along lines Y2-Y2′ and Y3-Y3′ of FIGS. 1A and 1B;

FIG. 2D is an enlarged cross-sectional view of portion “EX1” of FIG. 2A;

FIG. 2E is an enlarged cross-sectional view of portion “EX1A” of FIG. 2D;

FIG. 2F is an enlarged cross-sectional view of portion “EX1B” of FIG. 2D;

FIGS. 3, 4, and 5 are each a cross-sectional view of an IC device according to embodiments;

FIGS. 6 and 7 are each a cross-sectional view of an IC device according to embodiments;

FIG. 8A is a plan layout diagram of wirings located at a front side of an IC device according to embodiments and other components located adjacent to the wirings;

FIG. 8B is a cross-sectional view taken along lines Y2-Y2′ and Y3-Y3′ of FIG. 8A;

FIG. 9A is a plan layout diagram of wirings located at a back side of an IC device according to embodiments and other components located adjacent to the wirings;

FIG. 9B is a cross-sectional view taken along line X1-X1′ of FIG. 9A;

FIG. 9C is a cross-sectional view taken along lines Y2-Y2′ and Y3-Y3′ of FIG. 9A; and

FIGS. 10A, 10B, 11A, 11B, 12 to 21, 22A, 22B, 23A, 23B, 24A, 24B, 25A, 25B, 25C, 26A, 26B, 27, 28A, 28B, 29 to 35, 36A, 36B, 37A, 37B, 38A, 38B, 39A, 39B, 40A and 40B are cross-sectional views of a process sequence of a method of manufacturing an IC device, according to embodiments, wherein FIGS. 10A, 11A, 12 to 21, 22A, 23A, 24A, 25A, 26A, 28A, 29 to 35, 36A, 37A, 38A, 39A, and 40A are cross-sectional views taken along line X1-X1′ of FIG. 1A, according to the process sequence, FIGS. 10B, 11B, 22B, 23B, 24B, and 25B are cross-sectional views taken along Y1-Y1′ of FIG. 1A, according to the process sequence, and FIGS. 25C, 26B, 27, 28B, 36B, 37B, 38B, 39B, and 40B are cross-sectional views taken along lines Y2-Y2′ and Y3-Y3′ of FIG. 1A, according the process sequence.

### DETAILED DESCRIPTION

Hereinafter, embodiments will be described in detail with reference to the accompanying drawings. The same reference numerals are used to denote the same elements in the drawings, and repeated descriptions thereof will be omitted.

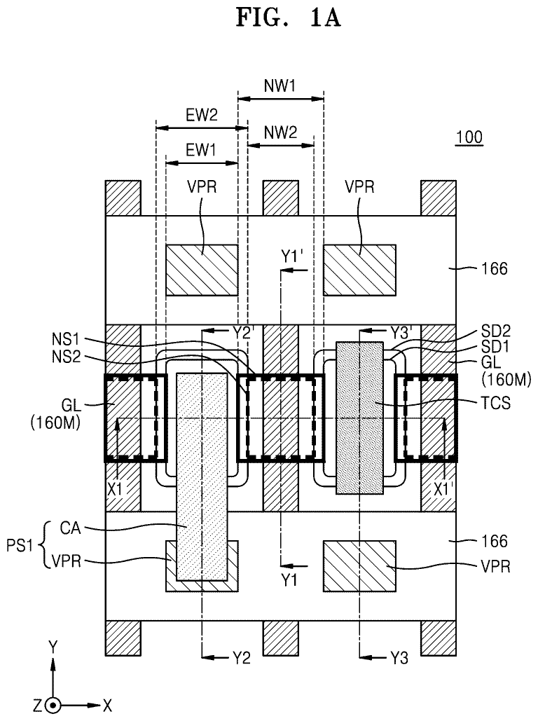

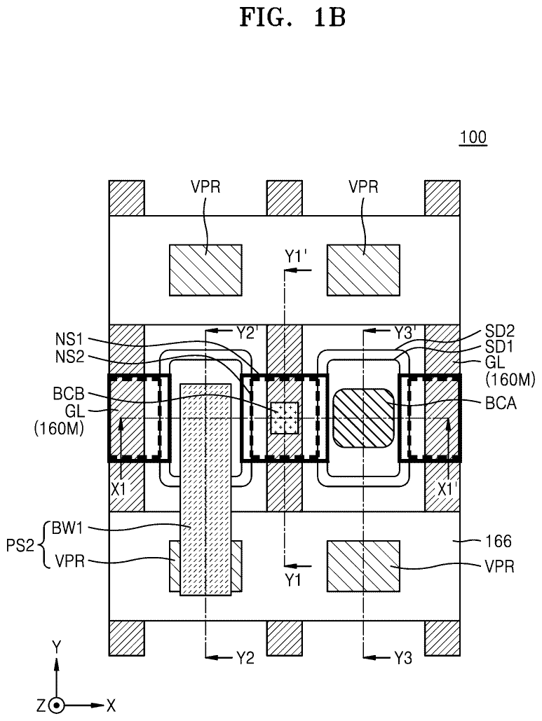

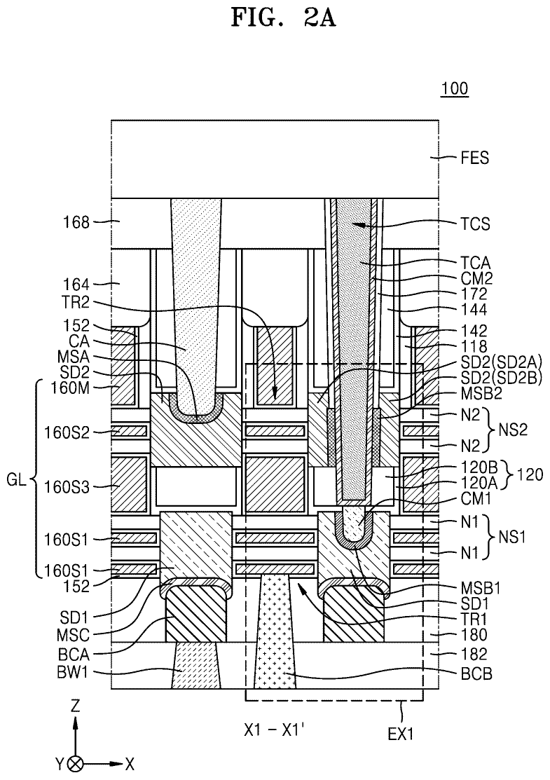

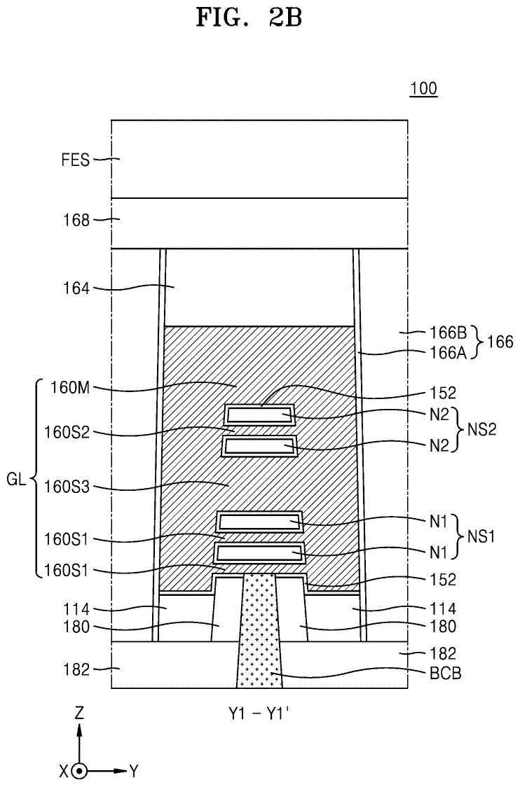

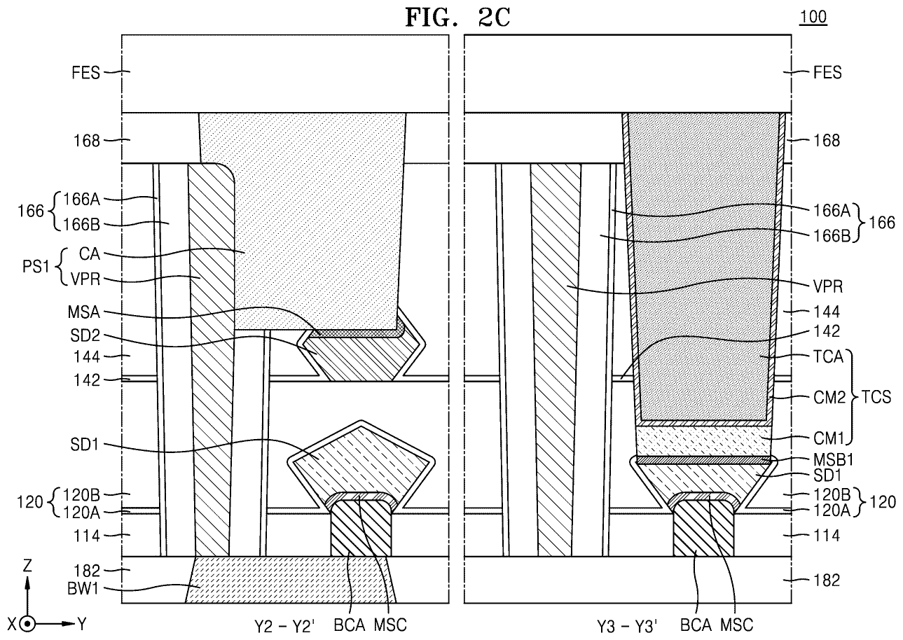

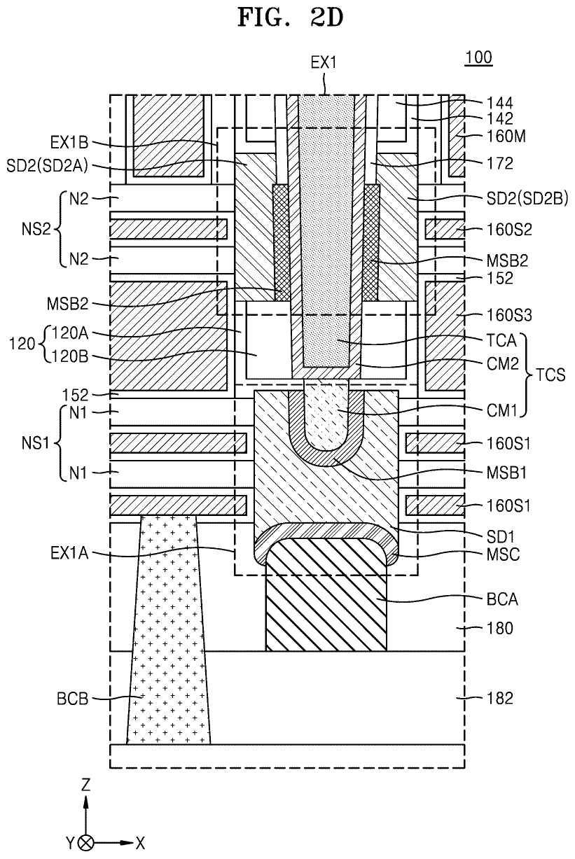

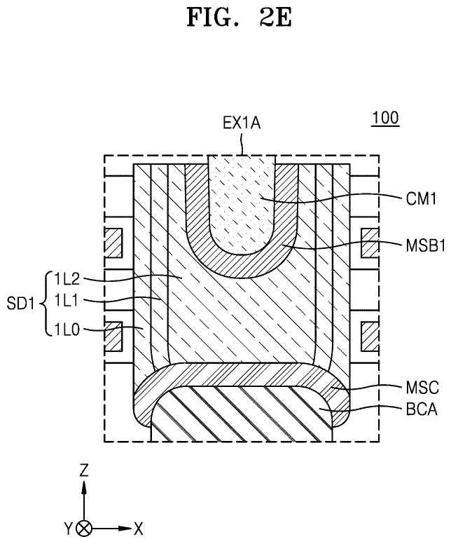

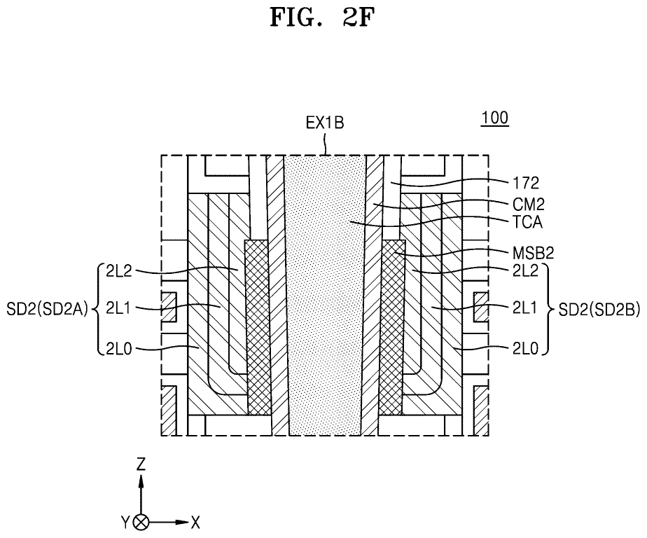

FIGS. 1A and 1B are each a plan layout diagram of an integrated circuit (IC) device 100 according to embodiments. More specifically, FIG. 1A is a plan layout diagram of wirings located at a front side of the IC device 100 and other components located adjacent to the wirings, and FIG. 1B is a plan layout diagram of wirings located at a back side of the IC device 100 and other components located adjacent to the wirings. FIG. 2A is a cross-sectional view taken along line X1-X1′ of FIGS. 1A and 1B, FIG. 2B is a cross-sectional view taken along line Y1-Y1′ of FIGS. 1A and 1B, FIG. 2C is a cross-sectional view taken along lines Y2-Y2′ and Y3-Y3′ of FIGS. 1A and 1B, FIG. 2D is an enlarged cross-sectional view of portion “EX1” of FIG. 2A, FIG. 2E is an enlarged cross-sectional view of portion “EX1A” of FIG. 2D, and FIG. 2F is an enlarged cross-sectional view of portion “EX1B” of FIG. 2D.

Referring to FIGS. 1A, 1B, and 2A to 2F, the IC device 100 may include a first transistor TR1 located at a first vertical level and a second transistor TR2 located at a second vertical level, which is higher than the first vertical level in a vertical direction (Z direction). The first transistor TR1 and the second transistor TR2 may be arranged to overlap one another in the vertical direction (Z direction). As used herein, a term “a vertical level” means a relative distance in the vertical direction (+Z direction or −Z direction). In the drawings, a vertical level being higher than another vertical level means that it is above the other vertical level in the +Z direction, and a vertical level being lower than another vertical level means that it is below the other vertical level in the −Z direction.

The first transistor TR1 may include a first nanosheet stack NS1 including a plurality of first nanosheets N1, which may provide a channel region, and a pair of first source/drain regions SD1, which are located on both sides of the first nanosheet stack NS1 and in contact with each of the plurality of first nanosheets N1. The pair of first source/drain regions SD1 may be spaced from one another in a first lateral direction (X direction) with the plurality of first nanosheets N1 included in the first nanosheet stack NS1 therebetween. The second transistor TR2 may include a second nanosheet stack NS2 including a plurality of second nanosheets N2, which may provide a channel region, and a pair of second source/drain regions SD2, which are located on both sides of the second nanosheet stack NS2 and in contact with each of the plurality of second nanosheets N2. The pair of second source/drain regions SD2 may be spaced apart from one another in the first lateral direction (X direction) with the plurality of second nanosheets N2 included in the second nanosheet stack NS2 therebetween. As used herein, the term “nanosheet” refers to a conductive structure having a cross-section that is substantially perpendicular to a direction in which current flows. The nanosheet may be interpreted as including a nanowire. The plurality of second nanosheets N2 included in the second nanosheet stack NS2 may overlap a plurality of nanosheets N1 included in a first nanosheet stack NS1 in the vertical direction (Z direction) and be apart from the plurality of nanosheets N1 in the vertical direction (Z direction). In the vertical direction (Z direction), a minimum separation distance between the first nanosheet stack NS1 and the second nanosheet stack NS2 may be greater than a minimum separation distance between the plurality of first nanosheets N1 included in the first nanosheet stack NS1 and be greater than a minimum separation distance between the plurality of second nanosheets N2 included in the second nanosheet stack NS2.

Each of the pair of second source/drain regions SD2 may overlap the first source/drain region SD1 in the vertical direction (Z direction). The second source/drain region SD2 may be spaced apart from the first source/drain region SD1 with an insulating pattern 120 therebetween in the vertical direction (Z direction). The insulating pattern 120 may have a double structure including a first insulating pattern 120A and a second insulating pattern 120B, which include different materials from one another. Each of the first insulating pattern 120A and the second insulating pattern 120B may include silicon nitride (SiN), silicon oxide (SiO), silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. As used herein, each of the terms “SiN,” “SiO,” “SiCN,” “SiBN,” “SiON,” “SiOCN,” “SiBCN,” and “SiOC” refers to a material including elements included therein, without referring to a chemical formula representing a stoichiometric relationship. In embodiments, a dielectric constant of the first insulating pattern 120A may be lower than a dielectric constant of the second insulating pattern 120B. For example, the first insulating pattern 120A may include a silicon nitride film, a SiCN film, a SiON film, or a SiOCN film, and the second insulating pattern 120B may include a silicon oxide film. However, a constituent material of each of the first insulating pattern 120A and the second insulating pattern 120B is not limited to the examples described above.

The first source/drain region SD1 and the second source/drain region SD2 may have different sizes and different shapes from one another. In embodiments, in a cross-sectional view (X-Z plane in FIG. 2A) taken in the first lateral direction (X direction), a planar size of the second source/drain region SD2 may be greater than a planar size of the first source/drain region SD1. As shown in FIG. 1A, in a plan view (X-Y plane) taken in the vertical direction (Z direction), the first lateral direction (X direction), a maximum width EW2 of the second source/drain region SD2 may be greater than a maximum width EW1 of the first source/drain region SD1. Each of the first source/drain region SD1 and the second source/drain region SD2 may include an epitaxially grown semiconductor layer. In embodiments, each of the first source/drain region SD1 and the second source/drain region SD2 may include a Group-IV element semiconductor, a Group IV-IV compound semiconductor, or a combination thereof.

The first source/drain region SD1 and the second source/drain region SD2 may include semiconductor materials of different conductivity types. In embodiments, the first transistor TR1 may include a p-channel metal-oxide semiconductor (PMOS) field-effect transistor (FET). The first source/drain region SD1 included in the first transistor TR1 may include a semiconductor layer doped with a p-type dopant. As used herein, a p type may be referred to as a first conductivity type. In embodiments, the second transistor TR2 may include an n-channel metal-oxide semiconductor (NMOS) FET. The second source/drain region SD2 included in the second transistor TR2 may include a semiconductor layer doped with an n-type dopant. As used herein, an n type may be referred to as a second conductivity type.

For example, the first source/drain region SD1 may include a SiGe layer doped with a p-type dopant. The p-type dopant may be selected from boron (B) and gallium (Ga). As shown in FIG. 2A, a lowermost surface level of each of the pair of first source/drain regions SD1 included in the first transistor TR1 may be lower than a lowermost surface level of the first nanosheet stack NS1, and an uppermost surface level of each of the pair of first source/drain regions SD1 may be higher than or equal to an uppermost surface level of the first nanosheet stack NS1. As shown in FIG. 2E, the first source/drain region SD1 may include a first buffer layer 1L0, a second buffer layer 1L1, and a main body layer 1L2, which are sequentially arranged from a bottom surface and a sidewall of the first source/drain region SD1 toward a center of the first source/drain region SD1. The first buffer layer 1L0, the second buffer layer 1L1, and the main body layer 1L2 may each include a Si₁₋ₓGeₓ layer (here, 0<x<1) doped with a p-type dopant and have different Ge content ratios from one another. In embodiments, a Ge content ratio of the second buffer layer 1L1 may be higher than a Ge content ratio of the first buffer layer 1L0 and lower than a Ge content ratio of the main body layer 1L2. For example, each of the first buffer layer 1L0, the second buffer layer 1L1, and the main body layer 1L2 may include a Si₁₋ₓGeₓ layer (here, 0<x<1) doped with a B element, and a B element concentration of the second buffer layer 1L1 may be higher than a B element concentration of the first buffer layer 1L0 and lower than a B element concentration of the main body layer 1L2.

For instance, the second source/drain region SD2 may include a Si layer doped with an n-type dopant or a SiC layer doped with an n-type dopant. The n-type dopant may be selected from phosphorus (P), arsenic (As), and antimony (Sb). As shown in FIG. 2A, a lowermost surface level of each of the pair of second source/drain regions SD2 included in the second transistor TR2 may be lower than a lowermost surface level of the second nanosheet stack NS2, and an uppermost surface level of each of the pair of second source/drain regions SD2 may be higher than or equal to an uppermost surface level of the second nanosheet stack NS2. As shown in FIG. 2F, the second source/drain region SD2 may include a first buffer layer 2L0, a second buffer layer 2L1, and a main body layer 2L2, which are sequentially arranged from a bottom surface and a sidewall of the second source/drain region SD2 toward a center of the second source/drain region SD2. In embodiments, each of the first buffer layer 2L0, the second buffer layer 2L1, and the main body layer 2L2 may include a Si layer doped with a P element, and a P element concentration of the second buffer layer 2L1 may be higher than a P element concentration of the first buffer layer 2L0 and lower than a P element concentration of the main body layer 2L2.

However, according to the disclosed concepts, a configuration of each of the first source/drain region SD1 and the second source/drain region SD2 is not limited to that described above. For example, the first source/drain region SD1 included in the first transistor TR1 may include a semiconductor layer doped with an n-type dopant, and the second source/drain region SD2 included in the second transistor TR2 may include a semiconductor layer doped with an n-type dopant.

The IC device 100 may include a plurality of gate lines GL. Each of the plurality of gate lines GL may be arranged between the pair of first source/drain regions SD1, which are adjacent to one another in the first lateral direction (X direction), and the pair of second source/drain regions SD2, which are adjacent to one another in the first lateral direction (X direction). The plurality of gate lines GL may be arranged adjacent to at least one first source/drain region SD1 and at least one second source/drain region SD2 in the first lateral direction (X direction). Each of the plurality of gate lines GL may surround the plurality of first nanosheets N1 and the plurality of second nanosheets N2, which overlap one another in the vertical direction (Z direction) and be spaced apart in the first lateral direction (X direction) from each of the first source/drain region SD1 and the second source/drain region SD2, which is adjacent to the corresponding one of the gate lines GL. Each of the plurality of gate lines GL may extend lengthwise in a second lateral direction (Y direction), which is perpendicular to the first lateral direction (X direction). The plurality of first nanosheets N1 and the plurality of second nanosheets N2, which overlap one another in the vertical direction (Z direction), may be surrounded by one gate line GL.

The first transistor TR1 and the second transistor TR2, which overlap one another in the vertical direction (Z direction), may share one gate line GL therebetween. That is, a gate line GL that constitutes a selected one of a plurality of first transistors TR1 may be the same as a gate line GL that constitutes the second transistor TR2 overlapping the selected one first transistor TR1 in the vertical direction (Z direction).

FIGS. 2A and 2B illustrate an example in which the first nanosheet stack NS1 includes two first nanosheets N1 and the second nanosheet stack NS2 includes two second nanosheets N2, but the disclosed concepts are not limited to the example shown in FIGS. 2A and 2B. For example, the first nanosheet stack NS1 may include one first nanosheet N1 or at least three first nanosheets N1, and the second nanosheet stack NS2 may include one second nanosheet N2 or at least three second nanosheets N2. The number of first nanosheet N1s included in the first nanosheet stack NS1 may be equal to or different from the number of second nanosheets N2 included in the second nanosheet stack NS2. FIGS. 1A and 1B illustrate an example in which each of the first nanosheet stack NS1 and the second nanosheet stack NS2 substantially has a tetragonal planar shape, but the disclosed concepts are not limited thereto Each of the first nanosheet stack NS1 and the second nanosheet stack NS2 may have various planar shapes as needed.

The plurality of first nanosheets N1 and the plurality of second nanosheets N2 may each include a channel region. For example, the plurality of first nanosheets N1 and the plurality of second nanosheets N2 may each have a thickness selected in a range of about 4 nm to about 6 nm, without being limited thereto. Herein, a thickness of each of the plurality of first nanosheets N1 and the plurality of second nanosheets N2 refers to a size in the vertical direction (Z direction). In embodiments, the plurality of first nanosheets N1 and the plurality of second nanosheets N2 may substantially have the same thickness in the vertical direction (Z direction). In embodiments, at least some of the plurality of first nanosheets N1 and the plurality of second nanosheets N2 may have different thicknesses in the vertical direction (Z direction).

In embodiments, the plurality of first nanosheets N1 included in one first nanosheet stack NS1 may have the same size in the first lateral direction (X direction). In embodiments, the plurality of first nanosheets N1 included in one first nanosheet stack NS1 may have different sizes in the first lateral direction (X direction). In embodiments, the plurality of second nanosheets N2 included in one second nanosheet stack NS2 may have the same size in the first lateral direction (X direction). In embodiments, the plurality of second nanosheets N2 included in one second nanosheet stack NSS may have different sizes in the first lateral direction (X direction). In the first lateral direction (X direction), a maximum width NW1 of the first nanosheet stack NS1 may be greater than a maximum width NW2 of the second nanosheet stack NS2.

As shown in FIGS. 2A and 2B, each of the plurality of gate lines GL may include a main gate portion 160M and a plurality of sub-gate portions (e.g., 160S1, 160S2, and 160S3), which are integrally connected to one another. The main gate portion 160M may cover a top surface of the second nanosheet stack NS2 and extend lengthwise in the second lateral direction (Y direction). The plurality of sub-gate portions (e.g., 160S1, 160S2, and 160S3) may include at least one first sub-gate portion 160S1, at least one second sub-gate portion 160S2, and a third sub-gate portion 160S3 between the first sub-gate portion 160S1 and the second sub-gate portion 160S2. The at least one first sub-gate portion 160S1 may have a surface facing the first source/drain region SD1 and a surface facing the first nanosheet N1 in the first lateral direction (X direction). The at least one second sub-gate portion 160S2 may cover the second nanosheet N2 at a vertical level higher than a vertical level of the third sub-gate portion 160S3. The at least one second sub-gate portion 160S2 may have a surface facing the second source/drain region SD2 and a surface facing the second nanosheet N2 in the first lateral direction (X direction).

As shown in FIG. 2A, in the first lateral direction (X direction), a maximum width of the second sub-gate portion 160S2 may be less than a maximum width of the first sub-gate portion 160S1. As shown in FIGS. 2A and 2B, in the vertical direction (Z direction), a thickness of each of the first and second sub-gate portions 160S1 and 160S2 may be less than a thickness of the main gate portion 160M. In the vertical direction (Z direction), a thickness of the third sub-gate portion 160S3 may be less than or equal to the thickness of the main gate portion 160M. The third sub-gate portion 160S3 may be located at the same vertical level as the insulating pattern 120 and have a surface facing the insulating pattern 120 in the first lateral direction (X direction). The gate line GL may include metal, metal nitride, metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from titanium nitride (TiN) and tantalum nitride (TaN). The metal carbide may include titanium aluminum carbide (TiAlC). However, a material included in the gate line GL is not limited to the examples described above.

A gate dielectric film 152 may be between the gate line GL and each of the plurality of first nanosheets N1 and the plurality of second nanosheets N2. In embodiments, the gate dielectric film 152 may have a stack structure of an interface film and a high-k dielectric film. The interface film may include a low-k dielectric material film having a dielectric constant of about 9 or lower, for example, a silicon oxide film, a silicon oxynitride film, or a combination thereof. In embodiments, the interface film may be omitted. The high-k dielectric film may include a material having a higher dielectric constant than a silicon oxide film. For instance, the high-k dielectric film may have a dielectric constant of about 10 to about 25. The high-k dielectric film may include hafnium oxide, without being limited thereto.

In embodiments, the plurality of first nanosheets N1 and the plurality of second nanosheets N2 may include semiconductor layers including the same element. In an example, the plurality of first nanosheets N1 and the plurality of second nanosheets N2 may each include a Si layer. In embodiments, the plurality of first nanosheets N1 and the plurality of second nanosheets N2 may each include an undoped Si layer. In embodiments, the plurality of first nanosheets N1 may include a Si layer doped with a dopant of the same conductivity type as a conductivity type of the first source/drain region SD1, and the plurality of second nanosheets N2 may include a Si layer doped with a dopant of the same conductivity type as a conductivity type of the second source/drain region SD2. In still embodiments, the plurality of first nanosheets N1 may include a Si layer doped with a dopant of a conductivity type opposite to the conductivity type of the first source/drain region SD1, and the plurality of second nanosheets N2 may include a Si layer doped with a dopant of a conductivity type opposite to the conductivity type of the second source/drain region SD2.

As shown in FIG. 2A, both sidewalls of the gate line GL may be covered by insulating spacers 118 on the second nanosheet stack NS2. The gate dielectric film 152 may include a portion between the gate line GL and the insulating spacer 118. The insulating spacer 118 may be spaced apart from the gate line GL with the gate dielectric film 152 therebetween. The insulating spacer 118 may include silicon nitride, SiCN, SiBN, SiON, SiOCN, SiBCN, SiOC, or a combination thereof. For example, the insulating spacer 118 may include a double film of an inner silicon nitride film in contact with the gate dielectric film 152 and a SiOCN film spaced apart from the gate dielectric film 152 with the inner silicon nitride film therebetween, without being limited thereto.

As shown in FIGS. 2A and 2B, a front-side top surface of the gate line GL may be covered by a capping insulating pattern 164. The capping insulating pattern 164 may include a silicon nitride film. The capping insulating pattern 164 may cover a top surface of each of the gate line GL, the gate dielectric film 152, and the insulating spacer 118. As use herein, a front side refers to an upper side (i.e., +Z direction side) above a vertical level at which the first nanosheet stack NS1 and the second nanosheet stack NS2 are arranged, in the vertical direction (Z direction).

As shown in FIG. 2A, the insulating spacer 118, the capping insulating pattern 164, and a front-side surface of the second source/drain region SD2 may be covered by an insulating structure. The insulating structure may include an insulating liner 142 and an inter-gate dielectric film 144. The insulating liner 142 may include silicon nitride (SiN), silicon oxide (SiO), SiCN, SiBN, SiON, SiOCN, SiBCN, SiOC, or a combination thereof. In embodiments, the insulating liner 142 may be omitted. The inter-gate dielectric film 144 may be located on the insulating liner 142. The inter-gate dielectric film 144 may include a silicon nitride film, a silicon oxide film, SiON, SiOCN, or a combination thereof. When the insulating liner 142 is omitted, the inter-gate dielectric film 144 may be in contact with a plurality of first source/drain regions SD1.

As shown in FIGS. 1A, 1B, 2B, and 2C, the IC device 100 may include a plurality of gate cut insulating structures 166 defining a length of the gate line GL in the second lateral direction (Y direction) and a plurality of via power rails VPR passing through the plurality of gate cut insulating structures 166 in the vertical direction (Z direction). The plurality of gate cut insulating structures 166 may each extend lengthwise in the first lateral direction (X direction). Each of the plurality of gate cut insulating structures 166 may include a barrier insulating film 166A and a main insulating film 166B surrounded by the barrier insulating film 166A. In embodiments, the barrier insulating film 166A may include a silicon nitride film, a SiCN film, a SiON film, or a SiOCN film, and the main insulating film 166B may include a silicon oxide film, without being limited thereto. The plurality of via power rails VPR may have smaller widths in the first lateral direction (X direction) and the second lateral direction (Y direction) toward a back side of the IC device 100 and away from a front side of the IC device 100. As used herein, a back side refers to a lower side (i.e., −Z direction side) below a vertical level at which the first nanosheet stack NS1 and the second nanosheet stack NS2 are arranged, in the vertical direction (Z direction).

In embodiments, each of the plurality of via power rails VPR may include only a meal plug including a single metal. In embodiments, each of the plurality of via power rails VPR may include a metal plug and a conductive barrier film surrounding the metal. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For instance, the conductive barrier film may include titanium (Ti), tantalum (Ta), tungsten (W), titanium nitride (TiN), tantalum (TaN), tungsten nitride (WN), tungsten carbon nitride (WCN), titanium silicon nitride (TiSiN), tantalum silicon nitride (TaSiN), tungsten silicon nitride (WSiN), or a combination thereof, without being limited thereto.

As shown in FIGS. 2A, 2B, and 2C, a top surface of the inter-gate dielectric film 144, the capping insulating pattern 164, and the gate cut insulating structure 166 may be covered by an upper insulating film 168. In embodiments, the upper insulating film 168 may include a silicon oxide film, without being limited thereto.

As shown in FIGS. 2A, 2C, and 2D, the IC device 100 may include a through contact structure TCS configured to be connected to each of the first source/drain region SD1 and the second source/drain region SD2 that overlap one another in the vertical direction (Z direction). The through contact structure TCS may pass through the upper insulating film 168, the inter-gate dielectric film 144, and the insulating liner 142 from a front side of the through contact structure TCS in the vertical direction (Z direction), pass through a selected one of a plurality of second source/drain regions SD2 and the insulating pattern 120 in the vertical direction (Z direction), and pass through, in the vertical direction (Z direction), at least a portion of the first source/drain region SD1, which overlaps the selected one second source/drain region SD2 in the vertical direction (Z direction). A sidewall of an upper portion of the through contact structure TCS, which is far from the first source/drain region SD1, may be surrounded by an insulating liner 172. The insulating liner 172 may include a portion between the upper insulating film 168 and the through contact structure TCS, a portion between the inter-gate dielectric film 144 and the through contact structure TCS, and a portion between the insulating liner 142 and the through contact structure TCS. The insulating liner 172 may include a silicon nitride film, a SiCN film, a SiON film, or a SiOCN film, without being limited thereto.

From among the plurality of second source/drain regions SD2, the second source/drain region SD2 passing through the through contact structure TCS may include a first local portion SD2A and a second local portion SD2B, which are spaced apart in the first lateral direction (X direction) from one another with the through contact structure TCS therebetween. The through contact structure TCS may pass through only an upper portion of the first source/drain region SD1 in the vertical direction (Z direction). Accordingly, sidewalls and a bottom surface of a lower portion of the through contact structure TCS may be surrounded by the first source/drain region SD1.

The through contact structure TCS may have a smaller width in each of the first lateral direction (X direction) and the second lateral direction (Y direction) as the through contact structure TCS gets closer to the back side of the IC device 100 in a direction away from the front side of the IC device 100 in the vertical direction (Z direction). The through contact structure TCS may have a smaller width in each of the first lateral direction (X direction) and the second lateral direction (Y direction) as the through contact structure TCS gets closer to the first source/drain region SD1 in a direction away from the second source/drain region SD2 in the vertical direction (Z direction).

The through contact structure TCS may include a lower contact plug CM1, a conductive contact liner CM2, and an upper contact plug TCA, which include different metals from one another. The upper contact plug TCA may pass through the second source/drain region SD2 in the vertical direction (Z direction). The upper contact plug TCA may have sidewalls facing the first local portion SD2A and the second local portion SD2B of the second source/drain region SD2 in the first lateral direction (X direction) and a bottom surface facing the first source/drain region SD1 in the vertical direction (Z direction). The upper contact plug TCA may be arranged apart from each of the first source/drain region SD1 and the second source/drain region SD2. The conductive contact liner CM2 may be between the second source/drain region SD2 and the upper contact plug TCA and surround the sidewall and the bottom surface of the upper contact plug TCA. The lower contact plug CM1 may be spaced apart in the vertical direction (Z direction) from the upper contact plug TCA with the conductive contact liner CM2 therebetween. The lower contact plug CM1 may include a portion surrounded by the first source/drain region SD1, and the conductive contact liner CM2 and the upper contact plug TCA may be spaced from the first source/drain region SD1 adjacent thereto in the vertical direction (Z direction).

In embodiments, the lower contact plug CM1, the conductive contact liner CM2, and the upper contact plug TCA, which are included in the through contact structure TCS, may include different metals selected from molybdenum (Mo), zirconium (Zr), tungsten (W), copper (Cu), cobalt (Co), ruthenium (Ru), manganese (Mn), titanium (Ti), tantalum (Ta), and aluminum (Al). For example, the lower contact plug CM1 may include Mo, the conductive contact liner CM2 may include Zr, the upper contact plug TCA may include W, without being limited thereto.

As shown in FIGS. 2A and 2D, a first metal silicide film MSB1 may be between the first source/drain region SD1 and the through contact structure TCS, which are connected to one another, and a second metal silicide film MSB2 may be between the second source/drain region SD2 and the through contact structure TCS, which are connected to one another. The first metal silicide film MSB1 may be between the lower contact plug CM1 of the through contact structure TCS and the first source/drain region SD1 and be in contact with each of the lower contact plug CM1 and the first source/drain region SD1. The second metal silicide film MSB2 may be between the conductive contact liner CM2 and the second source/drain region SD2 and be in contact with each of the conductive contact liner CM2 and the second source/drain region SD2. The second metal silicide film MSB2 may include a portion (referred to as a first portion) in contact with the first local portion SD2A of the second source/drain region SD2 adjacent thereto and a portion (referred to as a second portion) in contact with the second local portion SD2B of the second source/drain region SD2 adjacent thereto. Because the first local portion SD2A and the second local portion SD2B of the second source/drain region SD2 are spaced apart in the first lateral direction (X direction) from one another with the through contact structure TCS therebetween, the portion in contact with the first local portion SD2A of the second source/drain region SD2 and the portion in contact with the second local portion SD2B of the second source/drain region SD2 in the second metal silicide film MSB2 may also be spaced apart in the first lateral direction (X direction) from one another with the through contact structure TCS therebetween.

The first metal silicide film MSB1 and the second metal silicide film MSB2 may include different materials from one another. In embodiments, the first metal silicide film MSB1 and the second metal silicide film MSB2 may include different materials, which are selected from a Mo silicide, a Zr silicide, a W silicide, a Cu silicide, a Co silicide, a Ru silicide, a Mn silicide, a Ti silicide, a Ta silicide, and an Al silicide. For example, when the lower contact plug CM1 includes Mo, the first metal silicide film MSB1 may include Mo silicide. For example, when the conductive contact liner CM2 includes Zr, the second metal silicide film MSB2 may include Zr silicide.

The conductive contact liner CM2 of the through contact structure TCS may have an approximately U cross-sectional shape when viewed in each of a cross-section (X-Z plane of FIG. 2A) taken in the first lateral direction (X direction) and a cross-section (Y-Z plane of FIG. 2C) taken in the second lateral direction (Y direction). An inner surface of the conductive contact liner CM2 may be in contact with the upper contact plug TCA, and an outer surface of the conductive contact liner CM2 may be in contact with each of the lower contact plug CM1, the insulating pattern 120, the second metal silicide film MSB2, and the insulating liner 142.

As shown in FIGS. 2A and 2C, the IC device 100 may include a front-side contact CA configured to be connected to another selected one of the plurality of second source/drain regions SD2. The second source/drain region SD2 connected to the front-side contact CA may be spaced apart from the second source/drain region SD2 connected to the through contact structure TCS with one gate line GL therebetween in the first lateral direction (X direction).

The front-side contact CA may be configured to pass through the upper insulating film 168, the inter-gate dielectric film 144, and the insulating liner 142 from a front side of the front-side contact CA in the vertical direction (Z direction), pass through a portion of a selected one of the plurality of second source/drain regions SD2 in the vertical direction (Z direction), and be connected to the front-side surface of the second source/drain region SD2. A front-side metal silicide film MSA may be between the front-side contact CA and the front-side surface of the second source/drain region SD2 connected to the front-side contact CA. The front-side metal silicide film MSA may be in contact with each of the front-side contact CA and the second source/drain region SD2.

In embodiments, the front-side contact CA may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto. In embodiments, the conductive barrier film may be omitted. In embodiments, the front-side metal silicide film MSA may include a metal, which includes Zr, Ti, W, Ru, Nb, Mo, Hf, Ni, Co, Pt, Yb, Tb, Dy, Er, or Pd. For example, the front-side metal silicide film MSA may include Zr silicide. In embodiments, the front-side metal silicide film MSA between the front-side contact CA and the second source/drain region SD2 may include the same material as the second metal silicide film MSB2 between the through contact structure TCS and the front-side contact CA.

As shown in FIG. 2C, the front-side contact CA may be connected to a front-side end of a selected one of the plurality of via power rails VPR. A top surface of the front-side contact CA and a top surface of the via power rail VPR connected to the front-side contact CA may be located at different levels from one another.

Respective top surfaces of the front-side contact CA, the through contact structure TCS, and the upper insulating film 168 may be coplanar with one another. A front-side wiring structure FES may be arranged on the top surface of each of the front-side contact CA, the through contact structure TCS, and the upper insulating film 168. The front-side wiring structure FES may include a plurality of wiring layers, a plurality of via contacts, and a plurality of interlayer insulating layers covering the plurality of wiring layers and the plurality of via contacts. At least some of the plurality of wiring layers and the plurality of via contacts included in the front-side wiring structure FES may be configured to be connected to a front side of at least one of the plurality of gate lines GL, the front-side contact CA, the through contact structure TCS, and the plurality of via power rails VPR.

FIG. 2C illustrates a configuration in which the front-side contact CA is in contact with a top surface and a sidewall of the via power rail VPR adjacent thereto so that the front-side contact CA may be connected to the via power rail VPR adjacent thereto. However, the inventive concept is not limited thereto. For example, unlike shown in FIG. 2C, the front-side contact CA and the via power rail VPR may be configured to be connected to one another through at least one wiring layer and/or at least one via contact included in the front-side wiring structure FES.

As shown in FIGS. 2A to 2D, a back-side bottom surface of each of the plurality of gate lines GL may be covered by a device isolation film 114 and a first back-side insulating film 180 with the gate dielectric film 152 therebetween. Each of the device isolation film 114 and the first back-side insulating film 180 may include a silicon oxide film, a silicon nitride film, or a combination thereof.

The IC device 100 may include a plurality of back-side contacts BCA, which pass through the device isolation film 114 and the first back-side insulating film 180 in the vertical direction (Z direction). Each of the plurality of back-side contacts BCA may be configured to be connected to the back-side surface of the first source/drain region SD1 adjacent thereto from a back side of the first source/drain region SD1. A back-side metal silicide film MSC may be between the back-side contact BCA and the first source/drain region SD1. The back-side metal silicide film MSC may be in contact with each of the back-side contact BCA and the first source/drain region SD1.

In embodiments, the back-side contact BCA may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto. In embodiments, the conductive barrier film may be omitted. In embodiments, the back-side metal silicide film MSC may include a metal, which includes Zr, Ti, W, Ru, Nb, Mo, Hf, Ni, Co, Pt, Yb, Tb, Dy, Er, or Pd.

As shown in FIGS. 2A and 2D, the plurality of back-side contacts BCA may include one back-side contact BCA, which is spaced apart in the vertical direction (Z direction) from the through contact structure TCS with one first source/drain region SD1 therebetween and configured to be connected to the one first source/drain region SD1. The lower contact plug CM1 of the through contact structure TCS may be spaced apart in the vertical direction (Z direction) apart from the back-side contact BCA with the first metal silicide film MSB1 and the first source/drain region SD1 therebetween.

As shown in FIGS. 2A and 2C, the plurality of back-side contacts BCA may include one back-side contact BCA, which is spaced apart in the vertical direction (Z direction) from the front-side contact CA with one first source/drain region SD1 and one second source/drain region SD2 overlapping one another in the vertical direction (Z direction) therebetween, and is configured to be connected to the one first source/drain region SD1. The one back-side contact BCA may overlap the front-side contact CA in the vertical direction (Z direction).

A bottom surface of each of the plurality of back-side contacts BCA, the plurality of via power rails VPR, the plurality of gate cut insulating structures 166), the device isolation film 114, and the first back-side insulating film 180 may be covered by a second back-side insulating film 182. The second back-side insulating film 182 may include a silicon oxide film, a silicon nitride film, or a combination thereof. The IC device 100 may include a back-side wiring layer BW1 and a back-side gate contact BCB, which pass through the second back-side insulating film 182 in the vertical direction (Z direction). At l east one of the plurality of back-side contacts BCA may be configured to be connected to a selected one of the plurality of via power rails VPR through the back-side wiring layer BW1.

At least one of the plurality of back-side contacts BCA may be configured to be connected to a selected one of the plurality of via power rails VPR. For example, as shown in FIGS. 2A and 2C, the back-side contact BCA, which overlaps the front-side contact CA in the vertical direction (Z direction), may be connected to a selected one of the plurality of via power rails VPR through the back-side wiring layer BW1.

As shown in FIGS. 2A, 2B, and 2D, the back-side gate contact BCB may be in contact with a back-side bottom surface of the gate line GL by passing through the second back-side insulating film 182, the first back-side insulating film 180, and the gate dielectric film 152 in the vertical direction (Z direction). Each of the back-side wiring layer BW1 and the back-side gate contact BCB may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include Ti, Ta, W, TiN, TaN, WN, WCN, TiSiN, TaSiN, WSiN, or a combination thereof, without being limited thereto. In embodiments, the conductive barrier film may be omitted.

The IC device 100 described with reference to FIGS. 1A, 1B, and 2A to 2F may include the first transistor TR1 and the second transistor TR2, which overlap one another in the vertical direction (Z direction), and the first transistor TR1 and the second transistor TR2 may have channel types of different conductivity types. When the IC device 100 has a device region with a reduced area due to downscaling, the first transistor TR1 and the second transistor TR2, which have the channel types of different conductivity types, may be stacked in the vertical direction (Z direction), and thus, the number of transistors per unit area may be further increased to increase the integration density of the IC device 100. Also, the IC device 100 may include the through contact structure TCS configured to be connected to each of the first source/drain region SD1 and the second source/drain region SD2, which overlap one another in the vertical direction (Z direction). Thus, an area required for forming wirings connected to each of the first source/drain region SD1 and the second source/drain region SD2 may be markedly reduced. Accordingly, the integration density of the IC device 100 may be further improved by minimizing an area required for forming wirings. In addition, the first metal silicide film MSB1 between the first source/drain region SD1 and the through contact structure TCS connected thereto and the second metal silicide film MSB2 between the second source/drain region SD2 and the through contact structure TCS connected thereto may include different constituent materials from one another. By individually selecting respective constituent materials of the first metal silicide film MSB1 and the second metal silicide film MSB2 according to conductivity types of the first source/drain region SD1 and the second source/drain region SD2, the electrical performances of the first transistor TR1 and the second transistor TR2 may be independently improved. Accordingly, the reliability of the IC device 100 may improve.

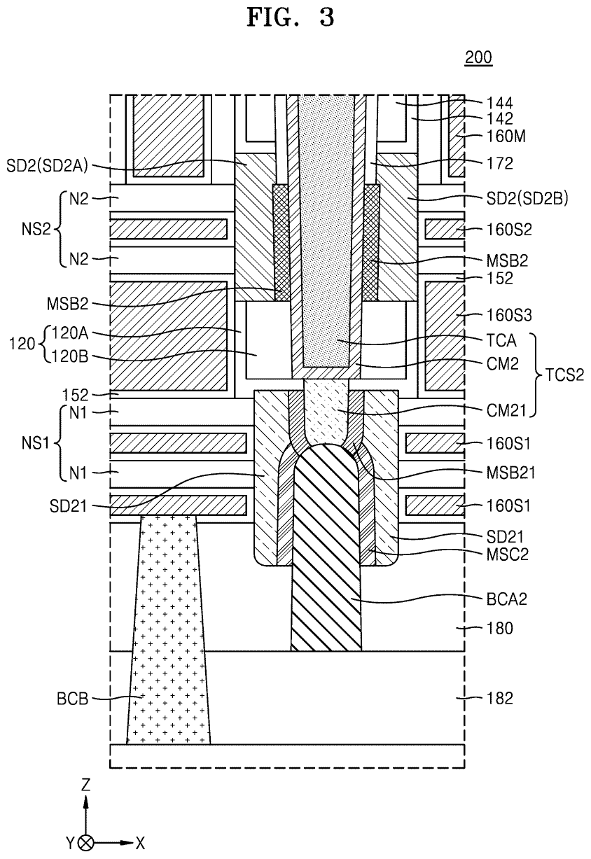

FIGS. 3, 4, and 5 are respectively cross-sectional views of IC devices 200, 300, and 400 according to embodiments. The IC devices 200, 300, and 400 may substantially have a plan layout similar to that shown in FIGS. 1A and 1B. FIGS. 3, 4, and 5 each illustrate a cross-sectional configuration of a portion corresponding to region “EX1” of FIG. 2A. In FIGS. 3, 4, and 5, the same reference numerals are used to denote the same elements as in FIGS. 1A, 1B, and 2A to 2F, and repeated descriptions thereof are omitted.

Referring to FIG. 3, the IC device 200 may substantially have the same configuration as the IC device 100 described with reference to FIGS. 1A, 1B, and 2A to 2F. However, the IC device 200 may include a first source/drain region SD21, a second source/drain region SD2 overlapping the first source/drain region SD21 in a vertical direction (Z direction), a through contact structure TCS2 passing through the second source/drain region SD2 and the insulating pattern 120 in the vertical direction (Z direction) and passing through a portion of the first source/drain region SD21 in the vertical direction (Z direction), a back-side contact BCA2 configured to be connected to a back-side surface of the first source/drain region SD21 from a back side of the first source/drain region SD21 by passing through a first back-side insulating film 180 in the vertical direction (Z direction), and a back-side metal silicide film MSC2 located between the back-side contact BCA2 and the first source/drain region SD21.

The through contact structure TCS2 may include a lower contact plug CM21, a conductive contact liner CM2, and an upper contact plug TCA, which include different metals from one another. A detailed configuration of the lower contact plug CM21 may substantially be the same as that of the lower contact plug CM1, which has been described with reference to FIGS. 2A, 2C, and 2D. However, the lower contact plug CM21 of the through contact structure TCS2 may overlap the back-side contact BCA2 in the vertical direction (Z direction) and contact the back-side contact BCA2. A bottom surface of the lower contact plug CM21 may be in contact with a top surface of the back-side contact BCA2. A first metal silicide film MSB21 may be between the first source/drain region SD21 and the lower contact plug CM21 of the through contact structure TCS2 connected to the first source/drain region SD21. The first metal silicide film MSB21 may substantially be the same as the first metal silicide film MSB1 described with reference to FIGS. 2A, 2C, and 2D. However, the first metal silicide film MSB21 may be spaced apart from the bottom surface of the lower contact plug CM21, which is in contact with the back-side contact BCA2, from among surfaces of the lower contact plug CM21. The first metal silicide film MSB21 may include a portion in contact with a sidewall of the lower contact plug CM21 and a portion in contact with the back-side contact BCA2. The back-side metal silicide film MSC2 may substantially be the same as the back-side metal silicide film MSC described with reference to FIGS. 2A, 2C, and 2D. However, the back-side metal silicide film MSC2 may be in contact with each of the first metal silicide film MSB21, the back-side contact BCA2, and the first source/drain region SD21.

In a cross-sectional view taken in a first lateral direction (X direction), the lower contact plug CM21 of the through contact structure TCS2 and the back-side contact BCA2 may approximately pass through the center of the first source/drain region SD21 in the vertical direction (Z direction). Thus, in a plan view (X-Y plane) taken in the vertical direction (Z direction), the first source/drain region SD21 may have a ring shape surrounding the lower contact plug CM21 and the back-side contact BCA2.

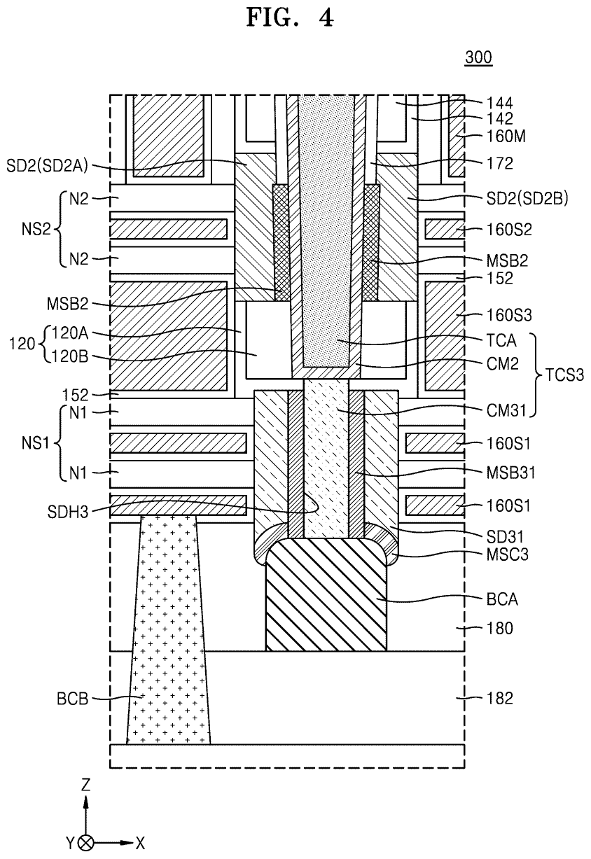

Referring to FIG. 4, the IC device 300 may substantially have the same configuration as the IC device 100 described with reference to FIGS. 1A, 1B, and 2A to 2F. However, the IC device 300 may include a first source/drain region SD31, a second source/drain region SD2 overlapping the first source/drain region SD31 in a vertical direction (Z direction), a through contact structure TCS3 passing through the second source/drain region SD2 and the insulating pattern 120 in the vertical direction (Z direction) and passing through the first source/drain region SD31 in the vertical direction (Z direction), and a back-side metal silicide film MSC3 located between a back-side contact BCA and the first source/drain region SD31.

The through contact structure TCS3 may include a lower contact plug CM31, a conductive contact liner CM2, and an upper contact plug TCA, which include different metals from one another. A detailed configuration of the lower contact plug CM31 may substantially be the same as that of the lower contact plug CM1, which has been described with reference to FIGS. 2A, 2C, and 2D. However, the lower contact plug CM31 of the through contact structure TCS3 may be located inside a through hole SDH3, which passes through the first source/drain region SD31 from a front-side surface of the first source/drain region SD31 to a back-side surface thereof in the vertical direction (Z direction). In a cross-sectional view taken in a first lateral direction (X direction), the lower contact plug CM31 of the through contact structure TCS3 may be located inside the through hole SDH3, which approximately passes through the center of the first source/drain region SD31 in the vertical direction (Z direction). Thus, in a plan view (X-Y plane) taken in the vertical direction (Z direction), the first source/drain region SD31 may have a ring shape surrounding the lower contact plug CM31.

The lower contact plug CM31 may overlap the back-side contact BCA in the vertical direction (Z direction) and contact the back-side contact BCA. A bottom surface of the lower contact plug CM31 may be in contact with a top surface of the back-side contact BCA. A first metal silicide film MSB31 may be between the first source/drain region SD31 and the lower contact plug CM31 of the through contact structure TCS3 connected to the first source/drain region SD31. The first metal silicide film MSB31 may substantially be the same as the first metal silicide film MSB1 described with reference to FIGS. 2A, 2C, and 2D. However, the first metal silicide film MSB31 may be spaced apart from the bottom surface of the lower contact plug CM31, which is in contact with the back-side contact BCA, from among surfaces of the lower contact plug CM31. The first metal silicide film MSB31 may include a portion in contact with a sidewall of the lower contact plug CM31 and a portion in contact with the back-side contact BCA. The back-side metal silicide film MSC3 may substantially be the same as the back-side metal silicide film MSC described with reference to FIGS. 2A, 2C, and 2D. However, the back-side metal silicide film MSC3 may be in contact with each of the first metal silicide film MSB31, the back-side contact BCA, and the first source/drain region SD31.

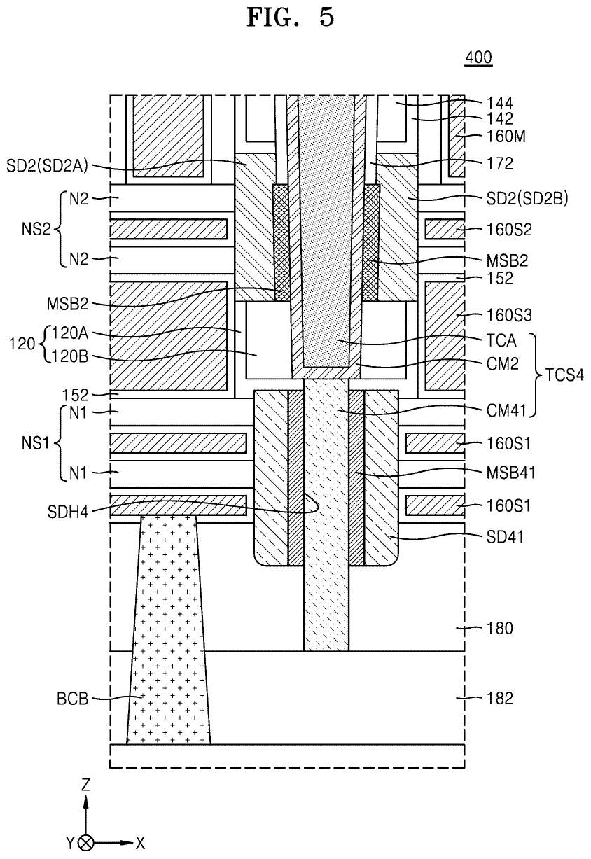

Referring to FIG. 5, the IC device 400 may substantially have the same configuration as the IC device 100 described with reference to FIGS. 1A, 1B, and 2A to 2F. However, the IC device 400 may include a first source/drain region SD41, a second source/drain region SD2 overlapping the first source/drain region SD41 in a vertical direction (Z direction), and a through contact structure TCS4 passing through the second source/drain region SD2 and the insulating pattern 120 in the vertical direction (Z direction) and passing through the first source/drain region SD41 in the vertical direction (Z direction).

The through contact structure TCS4 may include a lower contact plug CM41, a conductive contact liner CM2, and an upper contact plug TCA, which include different metals from one another. A detailed configuration of the lower contact plug CM41 may substantially be the same as that of the lower contact plug CM1, which has been described with reference to FIGS. 2A, 2C, and 2D. However, the lower contact plug CM41 of the through contact structure TCS4 may pass through the first source/drain region SD41 and a first back-side insulating film 180 in the vertical direction (Z direction). The lower contact plug CM41 of the through contact structure TCS4 may be located in a through hole SDH4, which passes through the first source/drain region SD41 from a front-side surface of the first source/drain region SD41 to a back-side surface thereof in the vertical direction (Z direction). In a cross-sectional view taken in a first lateral direction (X direction), the lower contact plug CM41 of the through contact structure TCS4 may be arranged inside the through hole SDH4, which approximately passes through the center of the first source/drain region SD41 in the vertical direction (Z direction). Thus, in a plan view (X-Y plane) taken in the vertical direction (Z direction), the first source/drain region SD41 may have a ring shape surrounding the lower contact plug CM41.

A bottom surface of the lower contact plug CM41 may be in contact with the second back-side insulating film 182. The IC device 400 may not include a back-side contact (refer to BCA in FIG. 2D) connected to the lower contact plug CM41. A first metal silicide film MSB41 may be between the first source/drain region SD41 and the lower contact plug CM41 of the through contact structure TCS4 connected to the first source/drain region SD41. The first metal silicide film MSB41 may substantially be the same as the first metal silicide film MSB1 described with reference to FIGS. 2A, 2C, and 2D. However, the first metal silicide film MSB41 may be in contact with only a sidewall facing the first source/drain region SD41, from among surfaces of the lower contact plug CM41.

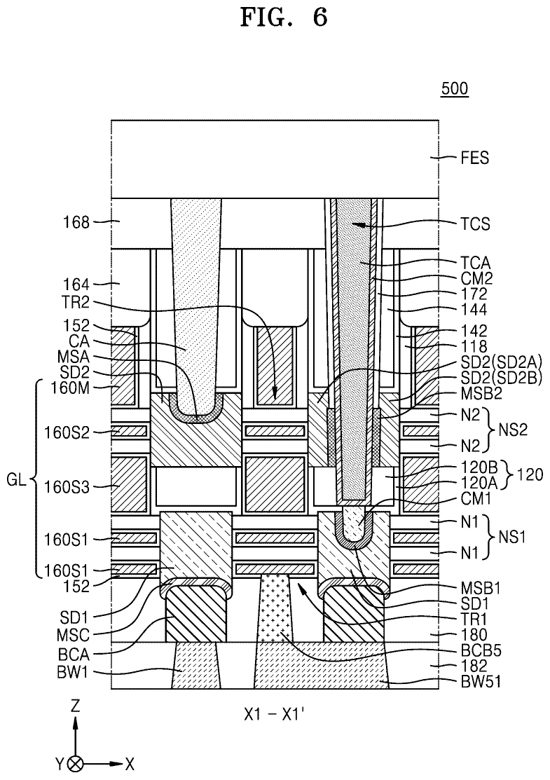

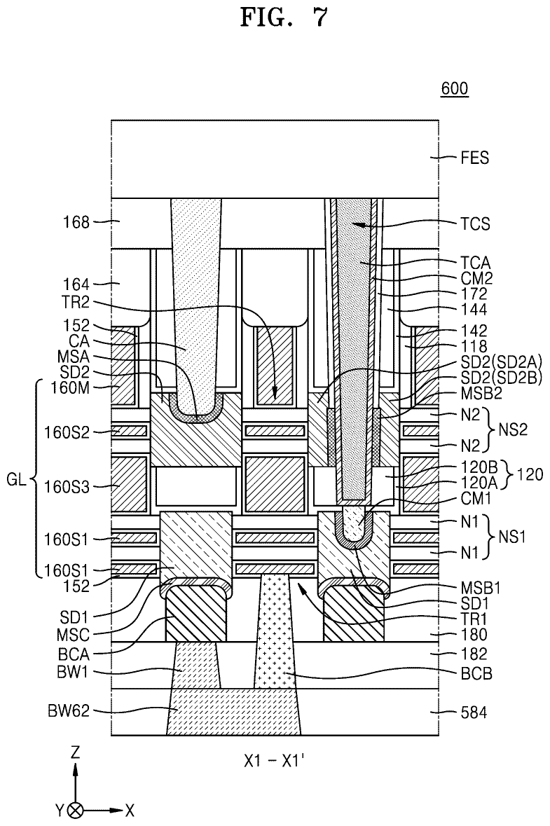

FIGS. 6 and 7 are respectively cross-sectional views of IC devices 500 and 600 according to embodiments. FIGS. 6 and 7 each illustrate a cross-sectional configuration of a portion corresponding to a cross-section taken along line X1-X1′ of FIGS. 1A and 1B. In FIGS. 6 and 7, the same reference numerals are used to denote the same elements as in FIGS. 1A, 1B, and 2A to 2F, and repeated descriptions thereof are omitted.

Referring to FIG. 6, the IC device 500 may substantially have the same configuration as the IC device 100 described with reference to FIGS. 1A, 1B, and 2A to 2F. However, the IC device 500 may include a back-side gate contact BCB5 and a back-side wiring layer BW51.

The back-side gate contact BCB5 may substantially have the same configuration as the back-side gate contact BCB described with reference to FIGS. 1B, 2A, 2B, and 2D. However, the back-side gate contact BCB5 may pass through a first back-side insulating film 180 in a vertical direction (Z direction) and contact a back-side bottom surface of the gate line GL. The back-side wiring layer BW51 may pass through a second back-side insulating film 182 in the vertical direction (Z direction) and be located at the same vertical level as the back-side wiring layer BW1. The back-side wiring layer BW51 may be spaced apart from the back-side wiring layer BW1 in a first lateral direction (X direction). A constituent material of the back-side wiring layer BW51 is the same as that of the back-side wiring layer BW1, which has been described above. From among a plurality of first source/drain regions SD1, a first source/drain region SD1 configured to be connected to a through contact structure TCS may be connected to the back-side gate contact BCB5 through a back-side contact BCA and the back-side wiring layer BW51.

Referring to FIG. 7, the IC device 600 may substantially have the same configuration as the IC device 100 described with reference to FIGS. 1A, 1B, and 2A to 2F. However, the IC device 600 may include a third back-side insulating film 584 and a back-side wiring layer BW62 that passes through the third back-side insulating film 584 in a vertical direction (Z direction) and contacts each of a back-side wiring layer BW1 and a back-side gate contact BCB.

The third back-side insulating film 584 may be spaced apart in the vertical direction (Z direction) from the first back-side insulating film 180 with a second back-side insulating film 182 therebetween. A gate line GL of a first transistor TR1 may be configured to one of a plurality of first source/drain regions SD1 through the back-side gate contact BCB, the back-side wiring layer BW62, the back-side wiring layer BW1, and a back-side contact BCA. FIG. 7 illustrates a configuration in which the gate line GL of the first transistor TR1 is configured to a first source/drain region SD1 that is connected to neither the front-side contact CA nor the through contact structure TCS2, from among the plurality of first source/drain regions SD1, through the back-side gate contact BCB and the back-side wiring layer BW62, but the disclosed concepts are not limited thereto. For example, the gate line GL of the first transistor TR1 may be configured to be connected to a first source/drain region SD1 connected to the through contact structure TCS, from among the plurality of first source/drain regions SD1, through the back-side gate contact BCB and the back-side wiring layer BW62. A constituent material of the third back-side insulating film 584 is the same as a constituent material of the second back-side insulating film 182, which has been described above. A constituent material of the back-side wiring layer BW62 is the same as that of the back-side wiring layer BW1, which has been described above.

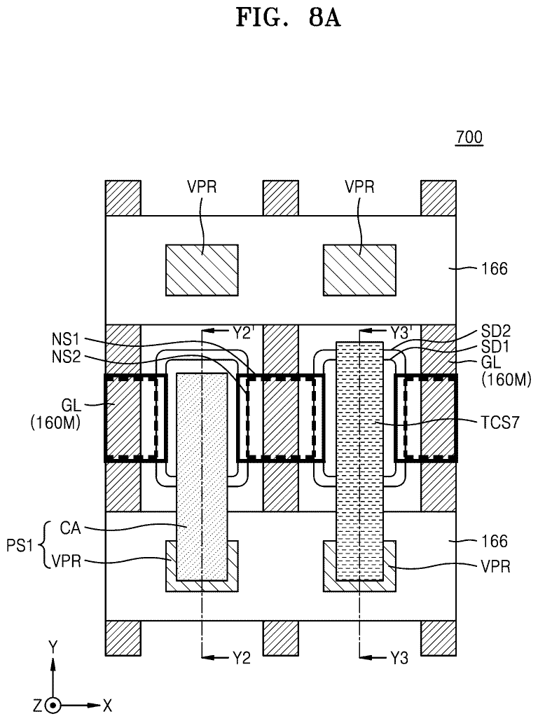

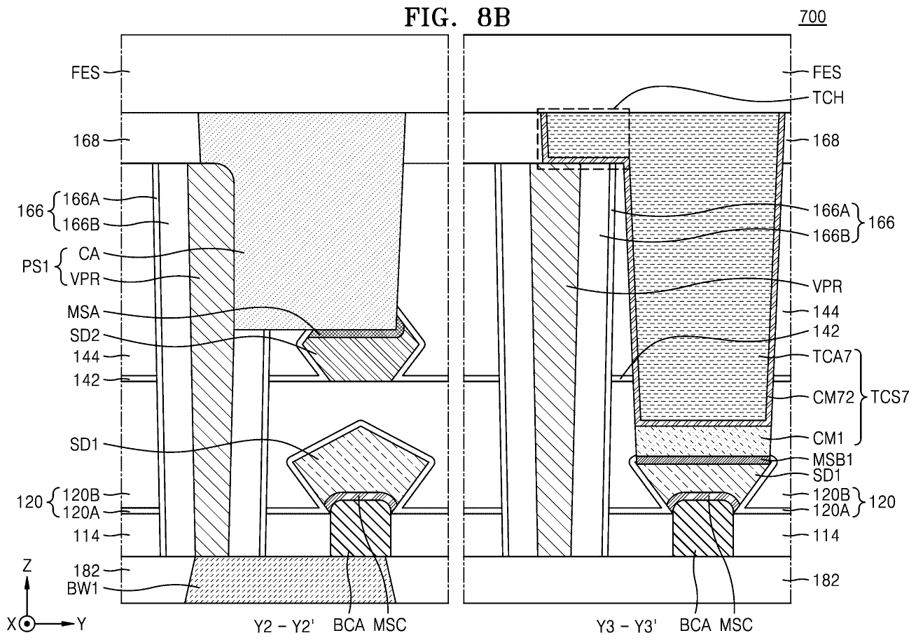

FIGS. 8A and 8B are diagrams of an IC device 700 according to embodiments, wherein FIG. 8A is a plan layout diagram of wirings located at a front side of the IC device 700 and other components located adjacent to the wirings, and FIG. 8B is a cross-sectional view taken along lines Y2-Y2′ and Y3-Y3′ of FIG. 8A. In FIGS. 8A and 8B, the same reference numerals are used to denote the same elements as in FIGS. 1A, 1B, and 2A to 2F, and repeated descriptions thereof are omitted.

Referring to FIGS. 8A and 8B, the IC device 700 may substantially have the same configuration as the IC device 100 described with reference to FIGS. 1A, 1B, and 2A to 2F. However, the IC device 700 may include a through contact structure TCS7.

The through contact structure TCS7 may substantially have the same configuration as the through contact structure TCS described with reference to FIGS. 1, 2A, 2C, and 2D. However, the through contact structure TCS7 may be configured to be connected to a selected one of the plurality of via power rails VPR.

The through contact structure TCS7 may include a lower contact plug CM1, a conductive contact liner CM72, and an upper contact plug TCA7, which include different metals from one another. The conductive contact liner CM72 and the upper contact plug TCA7 may pass through the second source/drain region SD2 in a vertical direction (Z direction). The conductive contact liner CM72 and the upper contact plug TCA7 may respectively and substantially have the same configurations as the conductive contact liner CM2 and the upper contact plug TCA described with reference to FIGS. 1A, 2A, 2C, and 2D. However, a front-side upper end of each of the conductive contact liner CM72 and the upper contact plug TCA7 may include a horizontal extension TCH. The horizontal extension TCH may cover a top surface of each of the inter-gate dielectric film 144, the gate cut insulating structure 166, and the via power rail VPR, extend in a first lateral direction (X direction), and be in direct contact with the via power rail VPR.

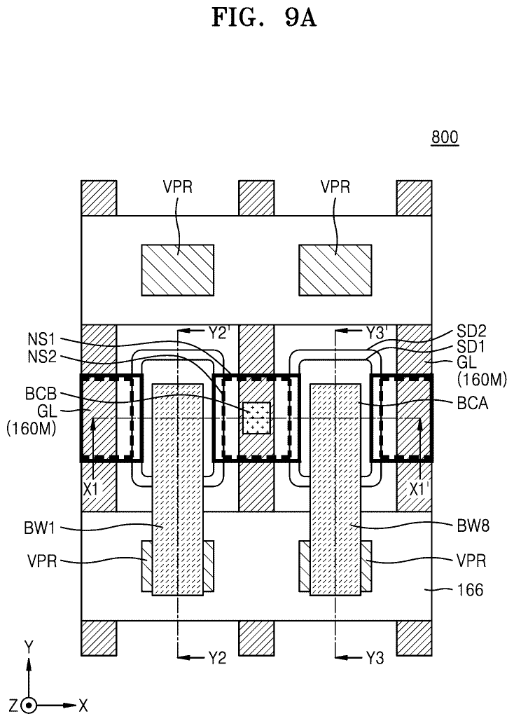

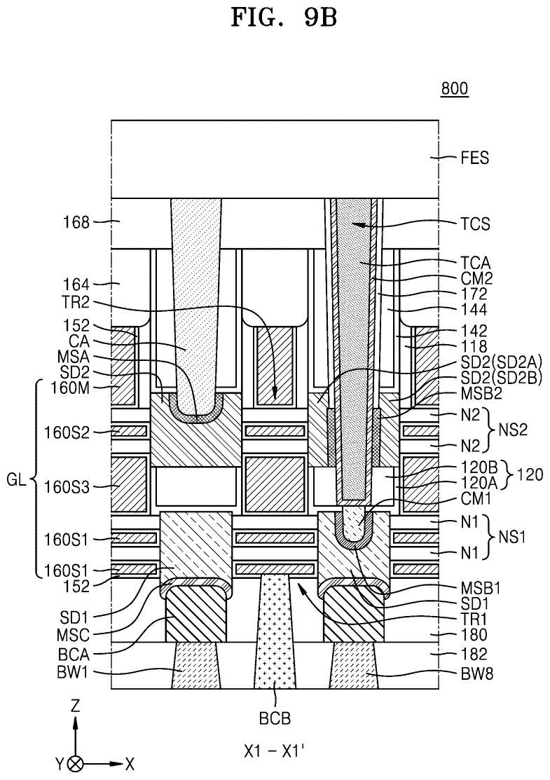

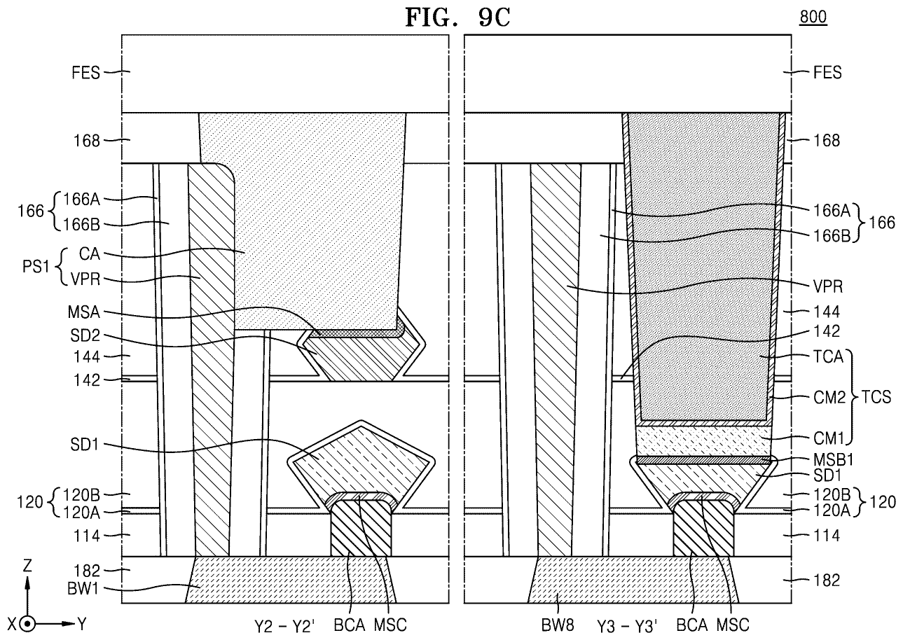

FIGS. 9A, 9B, and 9C are diagrams of an IC device 800 according to embodiments, wherein FIG. 9A is a plan layout diagram of wirings located at a back side of the IC device 800 and other components located adjacent to the wirings, FIG. 9B is a cross-sectional view taken along line X1-X1′ of FIG. 9A, and FIG. 9C is a cross-sectional view taken along lines Y2-Y2′ and Y3-Y3′ of FIG. 9A. In FIGS. 9A, 9B, and 9C, the same reference numerals are used to denote the same elements as in FIGS. 1A, 1B, and 2A to 2F, and repeated descriptions thereof are omitted.

Referring to FIGS. 9A, 9B, and 9C, the IC device 800 may substantially have the same configuration as the IC device 100 described with reference to FIGS. 1A, 1B, and 2A to 2F. However, the IC device 800 may further include a back-side wiring layer BW8 configured to provide an electrical connection path between a first source/drain region SD1 configured to be connected to a through contact structure TCS and a via power rail VPR.

From among a plurality of back-side contacts BCA, at least one back-side contact BCA may be configured to a selected one of a plurality of via power rails VPR through back-side wiring layers BW1 and BW8. The back-side contact BCA, which is located to overlap a front-side contact CA in a vertical direction (Z direction), may be connected to a selected one of the plurality of via power rails VPR through the back-side wiring layer BW1, and the back-side contact BCA, which is located to overlap the through contact structure TCS in the vertical direction (Z direction), may be connected to another selected one of the plurality of via power rails VPR through the back-side wiring layer BW8. The back-side wiring layer BW8 may pass through a second back-side insulating film 182 in the vertical direction (Z direction) and be located apart from the back-side wring layer BWL1 in a first lateral direction (X direction) at the same vertical level as the back-side wiring layer BW1.

In the IC devices 200, 300, 400, 500, 600, 700, and 800 described with reference to FIGS. 3 to 7, 8A, 8B, 9A, 9B and 9C, similarly to the IC device 100 described with reference to FIGS. 1A, 1B, and 2A to 2F, the first transistor TR1 and the second transistor TR2, which have channel types of different conductivity types, may be stacked in the vertical direction (Z direction), and thus, the number of transistors per unit area may be further increased to increase the integration density of the IC devices 200, 300, 400, 500, 600, 700, and 800. Also, the IC device 200, 300, 400, 500, 600, 700, or 800 may include the through contact structure TCS, TCS2, TCS3, TCS4, or TCS7 configured to be connected to each of the first source/drain region SD1, SD21, SD31, or SD41 and the second source/drain region SD2, which overlap one another in the vertical direction (Z direction). Thus, an area required for forming wirings connected to each of the first source/drain region SD1, SD21, SD31, or SD41 and the second source/drain region SD2 may be markedly reduced. Accordingly, the integration density of the IC devices 200, 300, 400, 500, 600, 700, and 800 may be further improved by minimizing an area required for forming wirings. Furthermore, the first metal silicide films MSB1, MSB21, MSB31, and MSB41 located between the first source/drain regions SD1, SD21, SD31, and SD41 and the through contact structures TCS, TCS2, TCS3, TCS4, and TCS7 connected thereto may include a constituent material different from that of the second metal silicide film MSB2 located between the second source/drain region SD2 and the through contact structure TCS connected thereto. By individually selecting respective constituent materials of the first metal silicide film MSB1, MSB21, MSB31, or MSB41 and the second metal silicide film MSB2 according to conductivity types of the first source/drain region SD1, SD21, SD31, or SD41 and the second source/drain region SD2, the electrical performances of the first transistor TR1 and the second transistor TR2 may be independently improved. Therefore, the reliability of the IC devices 200, 300, 400, 500, 600, 700, and 800 may improve.

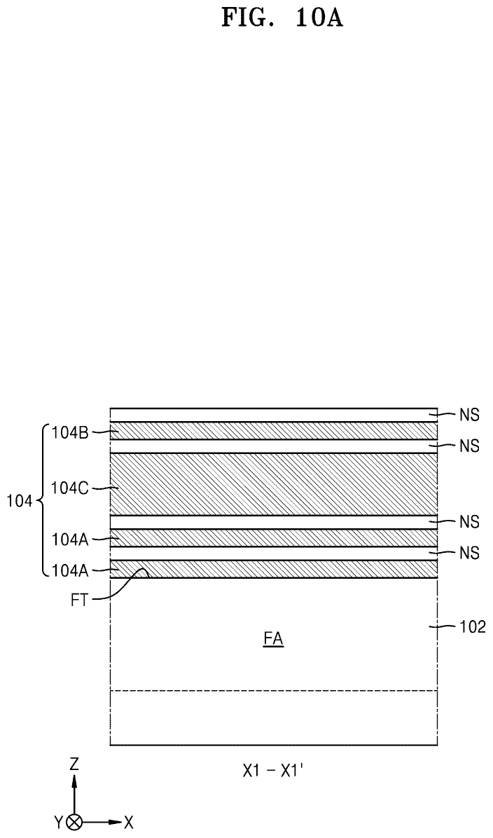

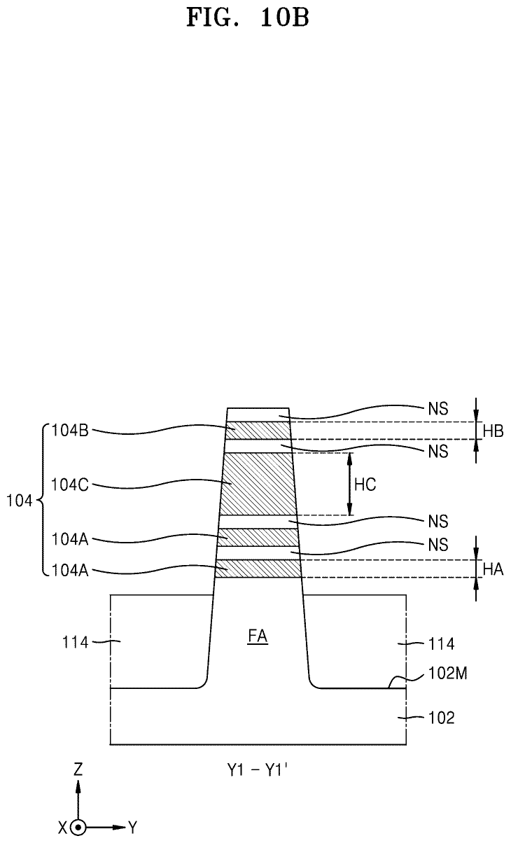

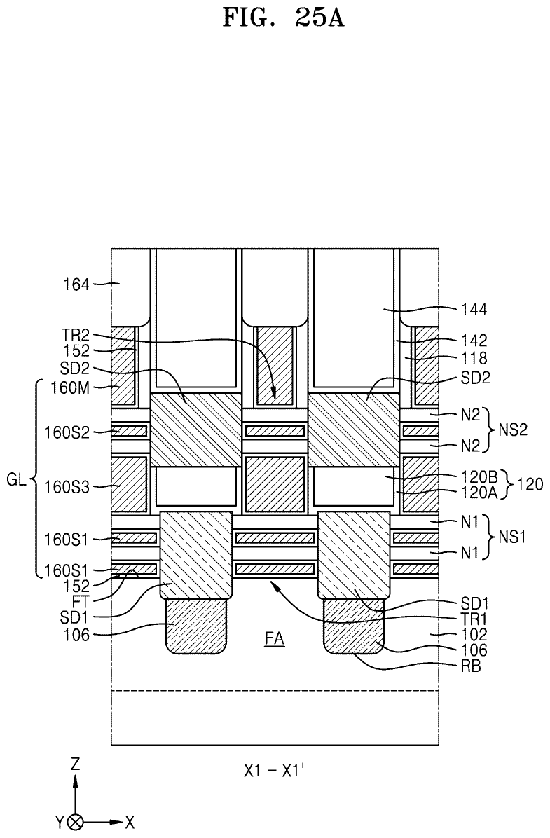

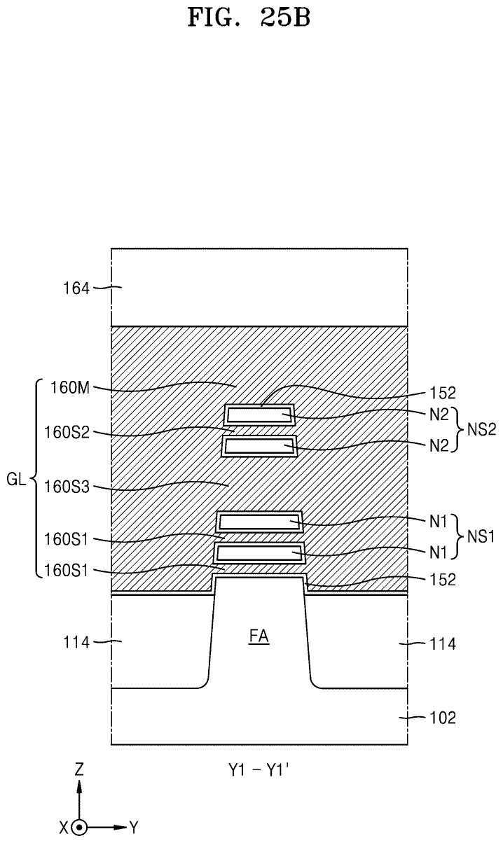

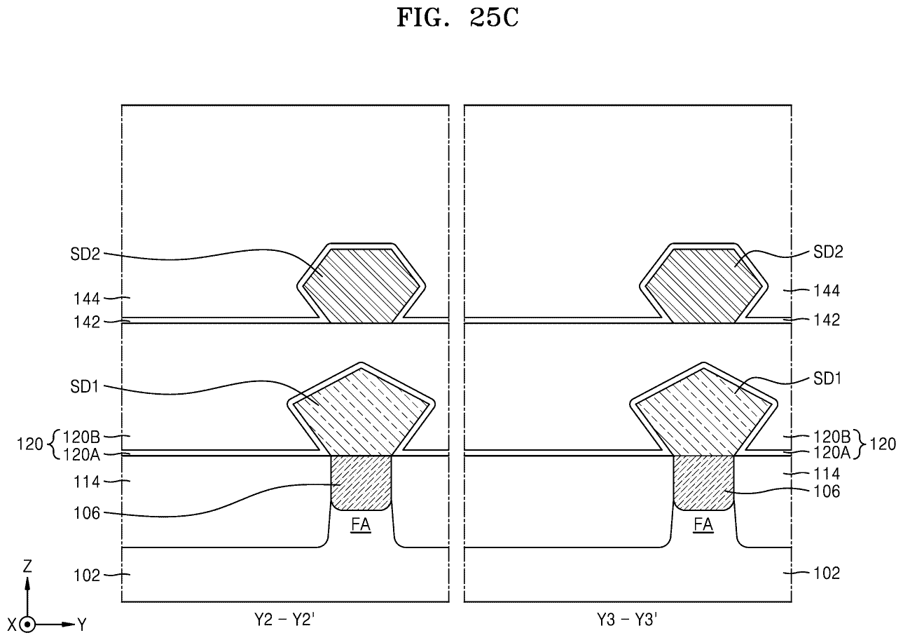

FIGS. 10A, 10B, 11A, 11B, 12 to 21, 22A, 22B, 23A, 23B, 24A, 24B, 25A, 25B, 25C, 26A, 26B, 27, 28A, 28B, 29 to 35, 36A, 36B, 37A, 37B, 38A, 38B, 39A, 39B, 40A and 40B are cross-sectional views of a process sequence of a method of manufacturing an IC device, according to embodiments, wherein FIGS. 10A, 11A, 12 to 21, 22A, 23A, 24A, 25A, 26A, 28A, 29 to 35, 36A, 37A, 38A, 39A, and 40A are cross-sectional views taken along line X1-X1′ of FIG. 1A, according to the process sequence, FIGS. 10B, 11B, 22B, 23B, 24B, and 25B are cross-sectional views taken along Y1-Y1′ of FIG. 1A, according to the process sequence, and FIGS. 25C, 26B, 27, 28B, 36B, 37B, 38B, 39B, and 40B are cross-sectional views taken along lines Y2-Y2′ and Y3-Y3′ of FIG. 1A, according the process sequence. An example of a method of manufacturing the IC device 100 shown in FIGS. 1A, 1B, and 2A to 2F is described with reference to FIGS. 10A, 10B, 11A, 11B, 12 to 21, 22A, 22B, 23A, 23B, 24A, 24B, 25A, 25B, 25C, 26A, 26B, 27, 28A, 28B, 29 to 35, 36A, 36B, 37A, 37B, 38A, 38B, 39A, 39B, 40A and 40B. In FIGS. 10A, 10B, 11A, 11B, 12 to 21, 22A, 22B, 23A, 23B, 24A, 24B, 25A, 25B, 25C, 26A, 26B, 27, 28A, 28B, 29 to 35, 36A, 36B, 37A, 37B, 38A, 38B, 39A, 39B, 40A and 40B, the same reference numerals are used to denote the same elements as in FIGS. 1A, 1B, and 2A to 2F, and repeated descriptions thereof are omitted.

Referring to FIGS. 10A and 10B, a plurality of sacrificial semiconductor layers 104 and a plurality of nanosheet semiconductor layers NS may be alternately stacked one-by-one on a substrate 102, and the plurality of sacrificial semiconductor layers 104, the plurality of nanosheet semiconductor layers NS, and the substrate 102 may be partially etched to form a fin-type active region FA in the substrate 102. After the fin-type active region FA is formed, a stack structure of the plurality of sacrificial semiconductor layers 104 and the plurality of nanosheet semiconductor layers NS may remain on the fin-type active region FA. Then, a device isolation film 114 covering a lower sidewall of the fin-type active region FA may be formed on the substrate 102.

The plurality of sacrificial semiconductor layers 104 may include at least one first sacrificial semiconductor layer 104A and at least one second sacrificial semiconductor layer 104B, which are stacked on the fin-type active region FA, and a third sacrificial semiconductor layer 104C between the first sacrificial semiconductor layer 104A and the second sacrificial semiconductor layer 104B. FIGS. 10A and 10B illustrate an example in which two first sacrificial semiconductor layers 104A are stacked on the fin-type active region FA in a vertical direction (Z direction), and one second sacrificial semiconductor layer 104B is stacked on the third sacrificial semiconductor layer 104C. In the vertical direction (Z direction), a thickness HA of the first sacrificial semiconductor layer 104A may be equal or similar to a thickness HB of the second sacrificial semiconductor layer 104B. A thickness HC of the third sacrificial semiconductor layer 104C may be greater than the thickness HA of the first sacrificial semiconductor layer 104A and be greater than the thickness HB of the second sacrificial semiconductor layer 104B.

The plurality of sacrificial semiconductor layers 104 and the plurality of nanosheet semiconductor layers NS may include semiconductor materials having different etch selectivities. In embodiments, each of the plurality of nanosheet semiconductor layers NS may include a Si layer, and each of the plurality of sacrificial semiconductor layers 104 may include a SiGe layer. In embodiments, the plurality of sacrificial semiconductor layers 104 may have a constant Ge concentration. The SiGe layer included in the plurality of sacrificial semiconductor layers 104 may have a constant Ge content, which is selected in a range of about 5 atomic percent (at %) to about 60 at %, for example, about 10 at % to about 40 at %. A Ge concentration in the SiGe layer included in the plurality of sacrificial semiconductor layers 104 may be variously selected as needed.

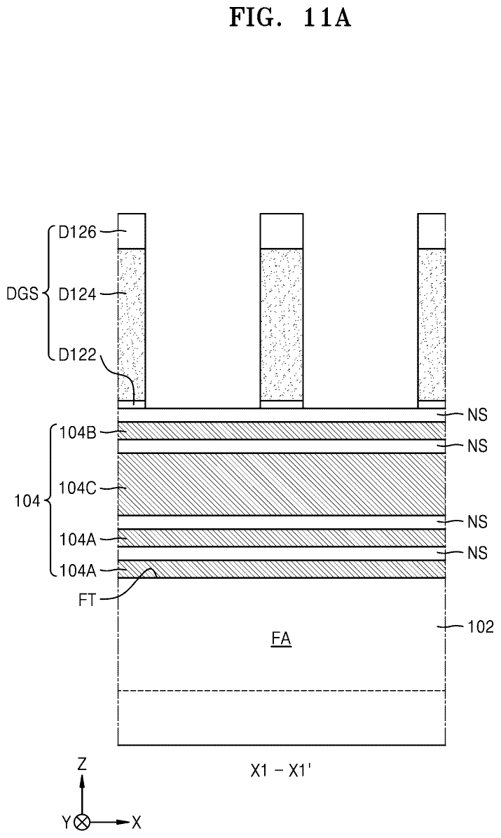

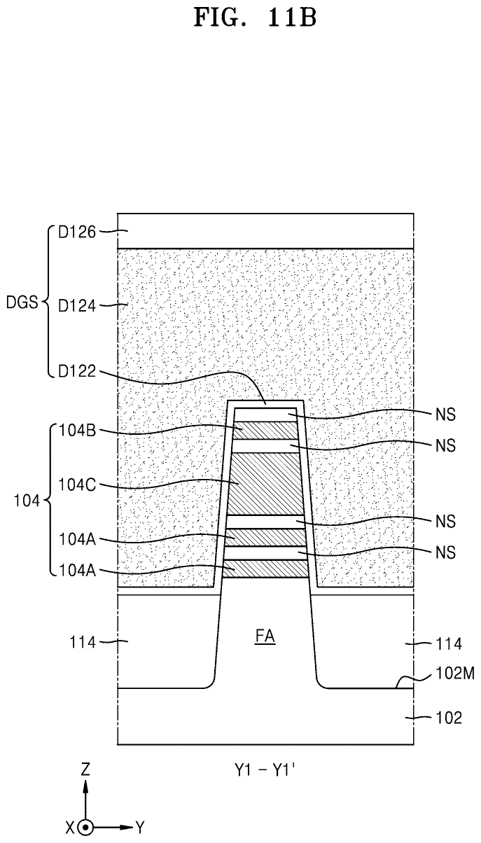

Referring to FIGS. 11A and 11B, a plurality of dummy gate structures DGS may be formed on the stack structure of the plurality of sacrificial semiconductor layers 104 and the plurality of nanosheet semiconductor layers NS and the device isolation film 114.

Each of the plurality of dummy gate structures DGS may be formed to extend lengthwise in a second lateral direction (Y direction). Each of the plurality of dummy gate structures DGS may include a structure in which an oxide film D122, a dummy gate layer D124, and a capping layer D126 are sequentially stacked. In embodiments, the dummy gate layer D124 may include polysilicon, and the capping layer D126 may include a silicon nitride film.

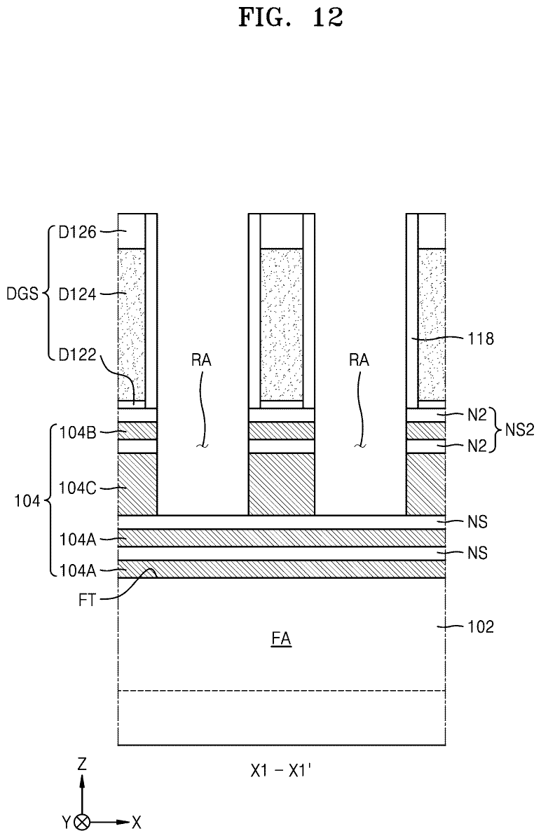

Referring to FIG. 12, a plurality of insulating spacers 118 may be formed to cover both sidewalls of each of the plurality of dummy gate structures DGS. Thereafter, portions of the plurality of sacrificial semiconductor layers 104 and portions of the plurality of nanosheet semiconductor layers NS may be removed by using the plurality of dummy gate structures DGS and the plurality of insulating spacers 118 as etch masks. Thus, a plurality of middle recesses RA may be formed, and the plurality of nanosheet semiconductor layers NS located on the third sacrificial semiconductor layer 104C may be divided into a plurality of second nanosheet stacks NS2. Each of the plurality of second nanosheet stacks NS2 may include a plurality of second nanosheets N2 stacked in the vertical direction (Z direction).

The plurality of middle recesses RA may be formed by using a dry etching process, a wet etching process, or a combination thereof. In embodiments, the plurality of middle recesses RA may be formed by using HCl gas, Cl₂ gas, and/or SF₃ gas, or other gases having similar etching characteristics, without being limited thereto.

In the resultant structure in which the plurality of second nanosheet stacks NS2 are formed, respective sidewalls of the plurality of second nanosheets N2, the second sacrificial semiconductor layer 104B, and the third sacrificial semiconductor layer 104C may be exposed through the plurality of middle recesses RA. Although FIG. 12 illustrates a case in which the nanosheet semiconductor layer NS is exposed at a bottom surface of each of the plurality of middle recesses RA, the disclosed concepts are not limited thereto. For example, after the plurality of middle recesses RA are formed, the third sacrificial semiconductor layer 104C may be exposed at the bottom surface of each of the plurality of middle recesses RA, and an uppermost one of the plurality of nanosheet semiconductor layers NS remaining on the substrate 102 may be covered by the third sacrificial semiconductor layer 104C so as not to be exposed through the plurality of middle recesses RA.

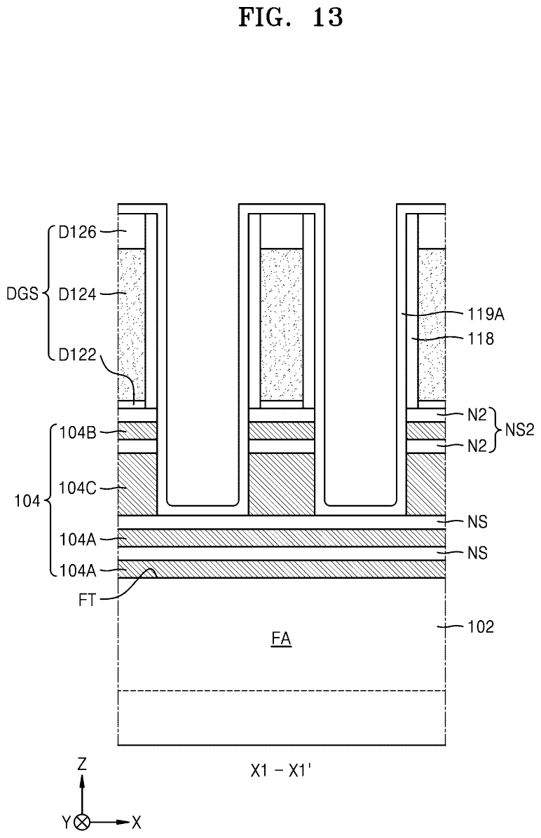

Referring to FIG. 13, a first insulating liner 119A may be formed to conformally cover exposed surfaces in the resultant structure of FIG. 12. The first insulating liner 119A may include silicon nitride (SiN), silicon oxide (SiO), SiCN, SiBN, SiON, SiOCN, SiBCN, SiOC, or a combination thereof. In embodiments, a constituent material of the first insulating liner 119A may be different from a constituent material of the insulating spacer 118.

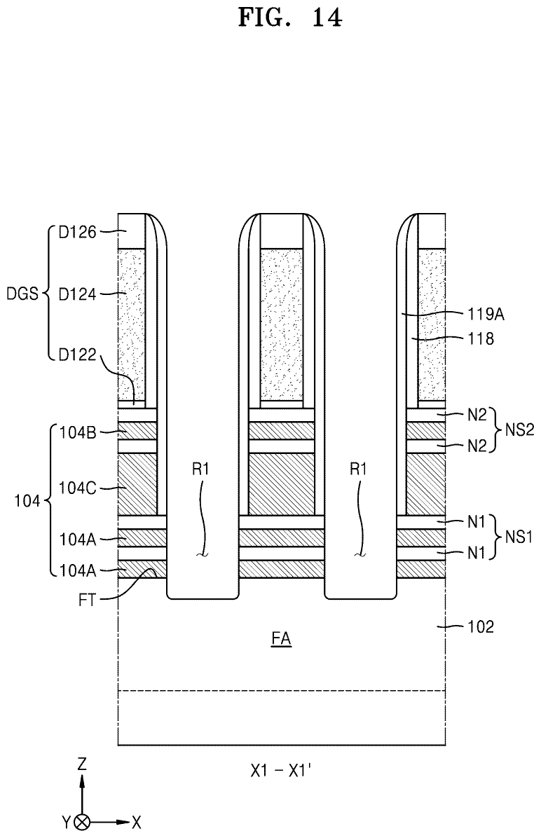

Referring to FIG. 14, in the resultant structure of FIG. 13, the first insulating liner 119A may be anisotropically etched to expose the nanosheet semiconductor layer NS at the bottom surface of each of the plurality of middle recesses RA. Subsequently, portions of the plurality of sacrificial semiconductor layers 104 and the plurality of nanosheet semiconductor layers NS, which respectively remain under the plurality of middle recesses (refer to RA in FIG. 12), and portions of the fin-type active regions FA may be removed by using the remaining portions of the plurality of dummy gate structures DGS, the plurality of insulating spacers 118, and the first insulating liner 119A as etch masks. Thus, a plurality of first recesses R1 may be formed, and the plurality of nanosheet semiconductor layers NS may be divided into a plurality of first nanosheet stacks NS1. Each of the plurality of first nanosheet stacks NS1 may include a plurality of first nanosheets N1 stacked in the vertical direction (Z direction).

In the resultant structure in which the plurality of first nanosheet stacks NS1 are formed, the plurality of first nanosheets N1, the first sacrificial semiconductor layer 104A, and the fin-type active region FA may be exposed through the plurality of first recesses R1. Each of the plurality of first recesses R1 shown in FIG. 12 may be connected to the middle recess RA. The bottom surface of each of the plurality of first recesses R1 may be at a lower vertical level than a fin top surface of the fin-type active region FA. However, the disclosed concepts are not limited thereto. For example, the bottom surface of each of the plurality of first recesses R1 may substantially be at the same vertical level as the fin top surface FT of the fin-type active region FA.

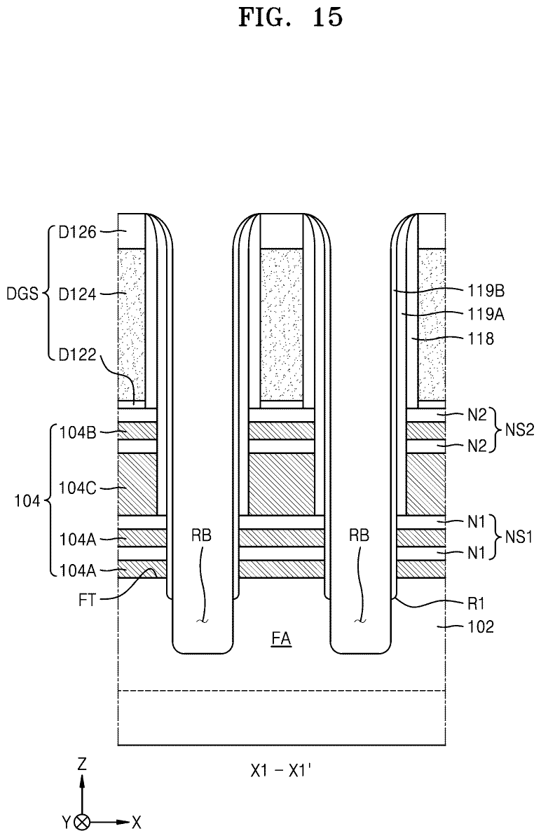

Referring to FIG. 15, a second insulating liner 119B may be formed to conformally cover exposed surfaces in the resultant structure of FIG. 14. The second insulating liner 119B may be anisotropically etched to expose the fin-type active region FA at the bottom surface of each of the plurality of first recesses R1. Subsequently, portions of the fin-type active region FA exposed through the second insulating liner 119B may be etched by using the respective remaining portions of the plurality of dummy gate structures DGS, the plurality of insulating spacers 118, the first insulating liner 119A, and the second insulating liner 119B as etch masks to form a plurality of back-side recesses RB.

The second insulating liner 119B may include silicon nitride (SiN), silicon oxide (SiO), SiCN, SiBN, SiON, SiOCN, SiBCN, SiOC, or a combination thereof. In embodiments, the second insulating liner 119B may include a material different from a constituent material of at least one of the first insulating liner 119A and the insulating spacer 118. For example, the second insulating liner 119B may include a material different from a constituent material of the first insulating liner 119A. A constituent material of the second insulating liner 119B may be the same as or different from a constituent material of the insulating spacer 118.

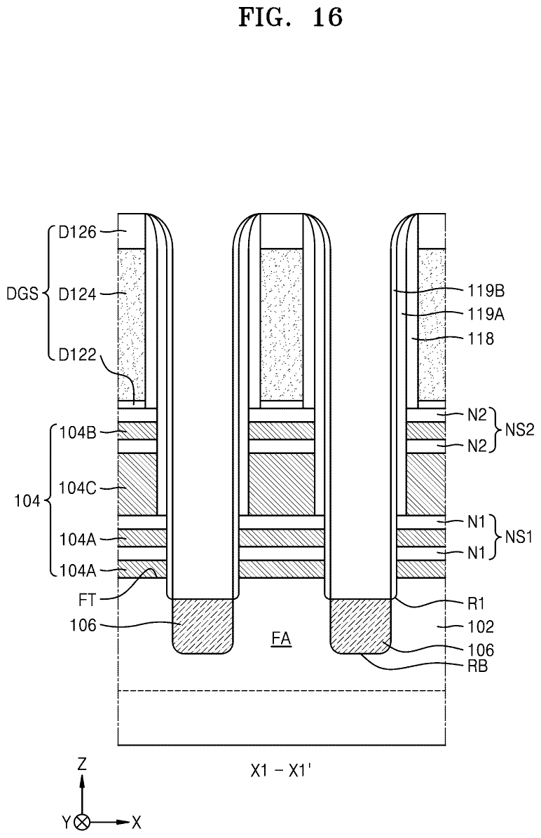

Referring to FIG. 16, in the resultant structure of FIG. 15, a plurality of place holders 106 filling the plurality of back-side recesses RB may be formed inside the fin-type active region FA.

In embodiments, to form the plurality of place holders 106, a semiconductor material may be epitaxially grown from surfaces of the fin-type active region FA, which are respectively exposed at the plurality of back-side recesses RB. The plurality of place holders 106 may respectively fill the plurality of back-side recesses RB while covering the fin-type active region FA. In embodiments, the plurality of place holders 106 may include a doped SiGe film or an undoped SiGe film. In embodiments, the plurality of place holders 106 may include a SiGe film having Ge content ratio higher than that of a plurality of first source/drain regions SD1 to be formed in a subsequent process. For example, the SiGe film included in the plurality of place holders 106 may have a Ge content ratio, which is selected in a range of about 20 at % to about 70 at %, without being limited thereto.

In embodiments, the plurality of place holders 106 may be formed by using a deposition process. For example, in the resultant structure of FIG. 15, an insulating film filling the plurality of back-side recesses RB may be formed and then etched back to form the plurality of place holders 106, which include the remaining portions of the insulating film. When the plurality of place holders 106 are formed by using a deposition process, the plurality of place holders 106 may include an aluminum oxide film, a titanium oxide film, a silicon nitride film, or a combination thereof, without being limited thereto.

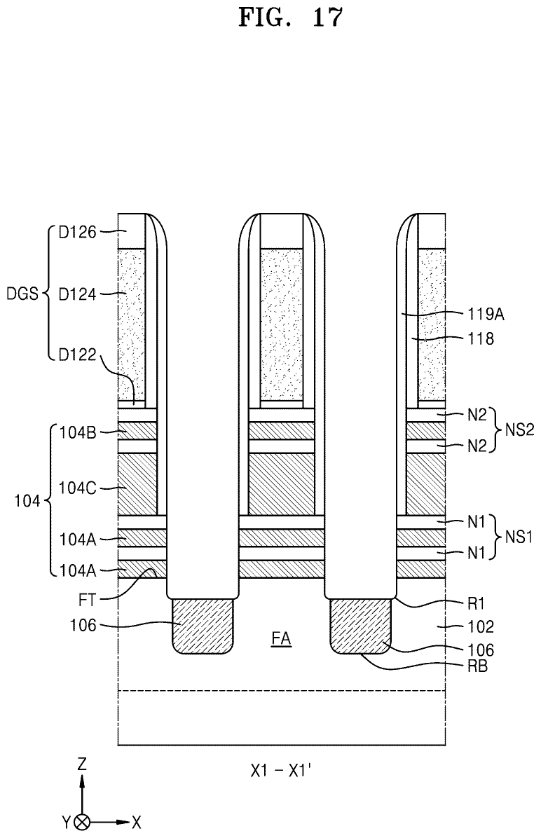

Referring to FIG. 17, the second insulating liner 119B may be selectively removed from the resultant structure of FIG. 16 to expose the first insulating liner 119A, the plurality of first nanosheets N1, and a plurality of first sacrificial semiconductor layers 104A.

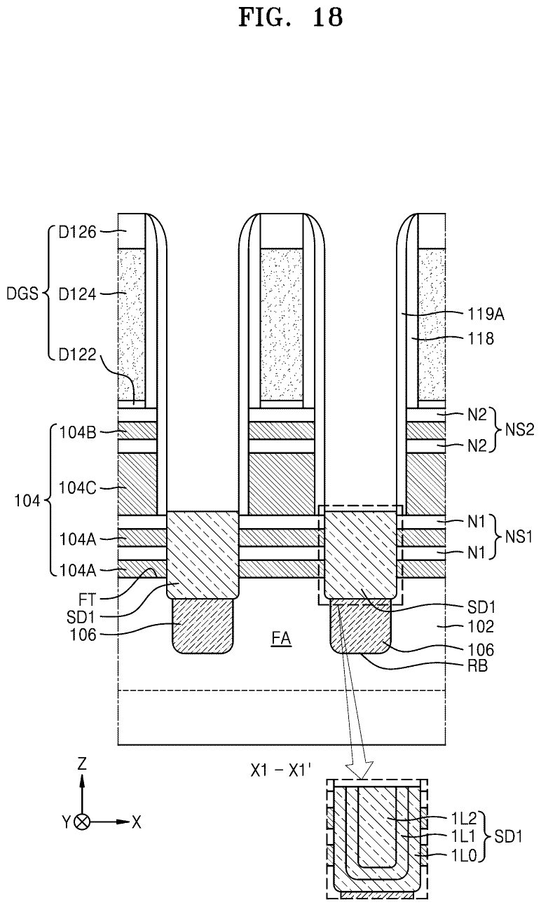

Referring to FIG. 18, in the resultant structure of FIG. 17, the plurality of first source/drain regions SD1 may be formed on the plurality of place holders 106.

The first source/drain region SD1 may be formed by performing a selective epitaxial growth (SEG) process. When the plurality of place holders 106 includes a SiGe film, during an initial operation of the SEG process, a semiconductor film may be locally and epitaxially grown from surfaces of the plurality of first nanosheets N1, which are exposed on the plurality of place holders 106, and a surface of the place holder 106. Thereafter, as the SEG process progresses, the semiconductor film may be gradually grown, and thus, the plurality of first source/drain regions SD1 shown in FIG. 18 may be obtained.

When the plurality of first source/drain regions SD1 include a SiGe layer doped with a p-type dopant, the SiGe layer doped with the p-type dopant may be formed by using a Si source and a Ge source. Silane (SiH₄), disilane (Si₂H₆), trisilane (Si₃H₈), and/or dichlorosilane (SiH₂Cl₂) may be used as the Si source. Germane (GeH₄), digermane (Ge₂H₆), trigermane (Ge₃H₈), tetragermane (Ge₄H₁₀), and/or dichlorogermane (Ge₂H₂Cl₂) may be used as the Ge source. The p-type dopant may be selected from B and Ga. Each of the plurality of first source/drain regions SD1 may be formed to include a first buffer layer 1L0, a second buffer layer 1L1, and a main body layer 1L2. Detailed configurations of the first buffer layer 1L0, the second buffer layer 1L1, and the main body layer 1L2 are the same as those described with reference to FIG. 2E.

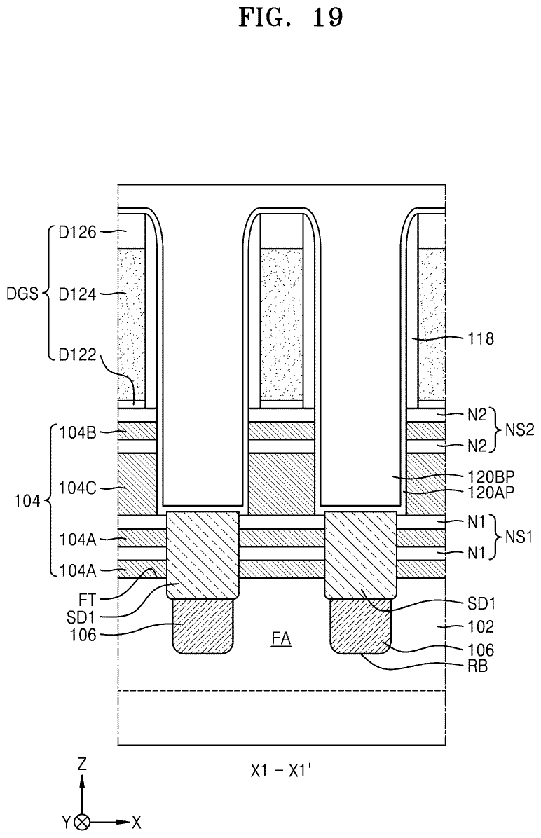

Referring to FIG. 19, the first insulating liner 119A may be selectively removed from the resultant structure of FIG. 18, and thus, the insulating spacer 118, the plurality of second nanosheets N2, the second sacrificial semiconductor layer 104B, and the third sacrificial semiconductor layer 104C may be exposed on each of the plurality of first source/drain regions SD1. Thereafter, a first insulating film 120AP may be formed to conformally cover surfaces of the obtained resultant structure, and a second insulating film 120BP filling respective spaces between the plurality of dummy gate structures DGS may be formed on the first insulating film 120AP. A constituent material of each of the first insulating film 120AP and the second insulating film 120BP may be the same as the constituent material of each of the first insulating pattern 120A and the second insulating pattern 120B, which has been described above.

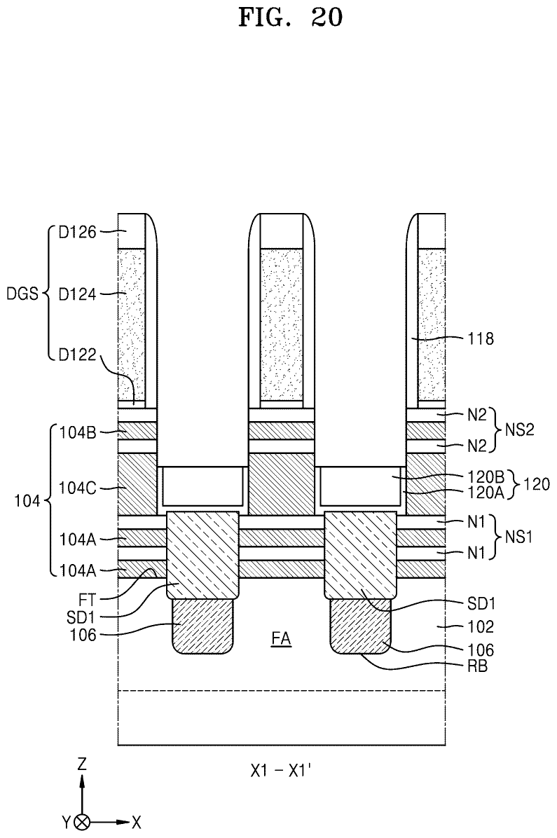

Referring to FIG. 20, the first insulating film 120AP and the second insulating film 120BP may be etched back from the resultant structure of FIG. 19, and thus, a plurality of insulating patterns 120 may be formed on the plurality of first source/drain regions SD1. Each of the plurality of insulating patterns 120 may include a first insulating pattern 120A and a second insulating pattern 120B, which respectively include the remaining portions of the first insulating film 120AP and the second insulating film 120BP.

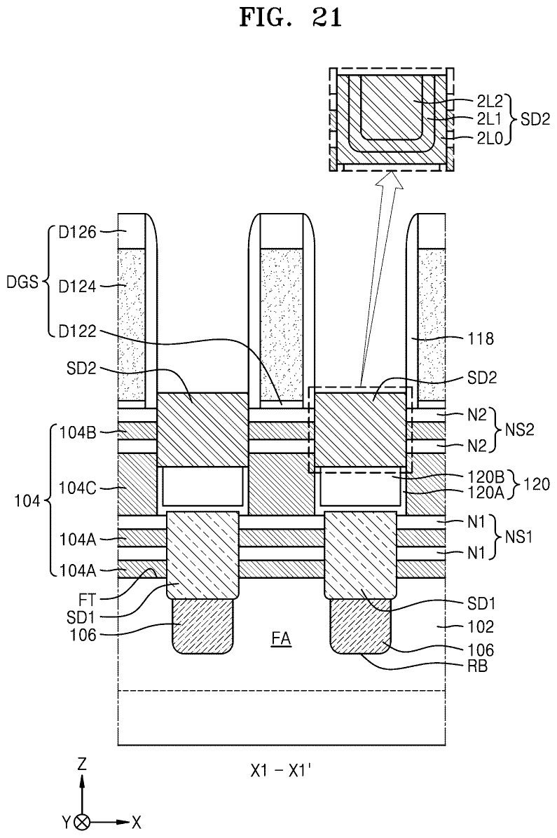

Referring to FIG. 21, a plurality of second source/drain regions SD2 may be formed on the plurality of insulating patterns 120 in the resultant structure of FIG. 20.

The plurality of second source/drain regions SD2 may be formed by performing an SEG process. In an initial operation of the SEG process, a semiconductor film may be locally and epitaxially grown from surfaces of the plurality of second nanosheets N2 exposed on the plurality of insulating patterns 120. Thereafter, as the SEG process progresses, the semiconductor film may be gradually grown, and thus, the plurality of second source/drain regions SD2 shown in FIG. 21 may be obtained.

In embodiments, when the plurality of second source/drain regions SD2 include a Si layer doped with an n-type dopant, a Si source may be used to form the plurality of second source/drain regions SD2 through the SEG process. Silane (SiH₄), disilane (Si₂H₆), trisilane (Si₃H₈), and/or dichlorosilane (SiH₂Cl₂) may be used as the Si source, without being limited thereto. The n-type dopant may be selected from phosphorus (P), arsenic (As), and antimony (Sb). Each of the plurality of second source/drain regions SD2 may be formed to include a first buffer layer 2L0, a second buffer layer 2L1, and a main body layer 2L2. Detailed configurations of the first buffer layer 2L0, the second buffer layer 2L1, and the main body layer 2L2 are the same as those described with reference to FIG. 2F.

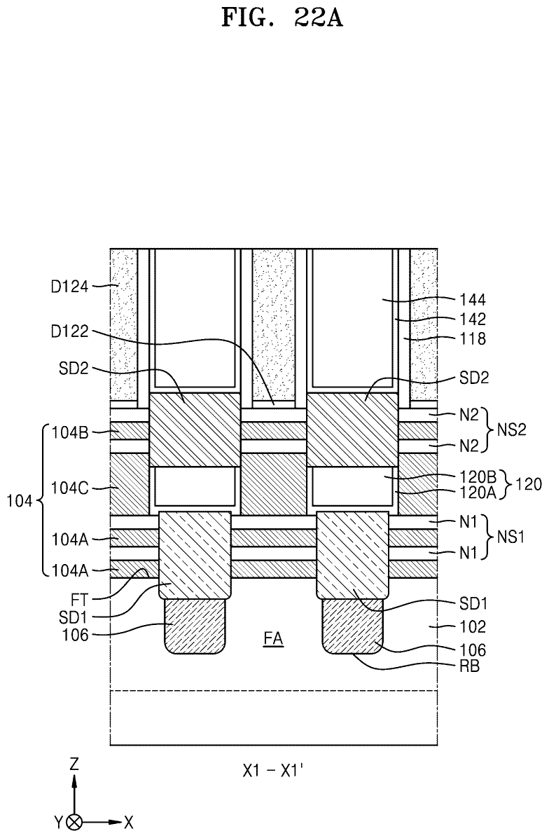

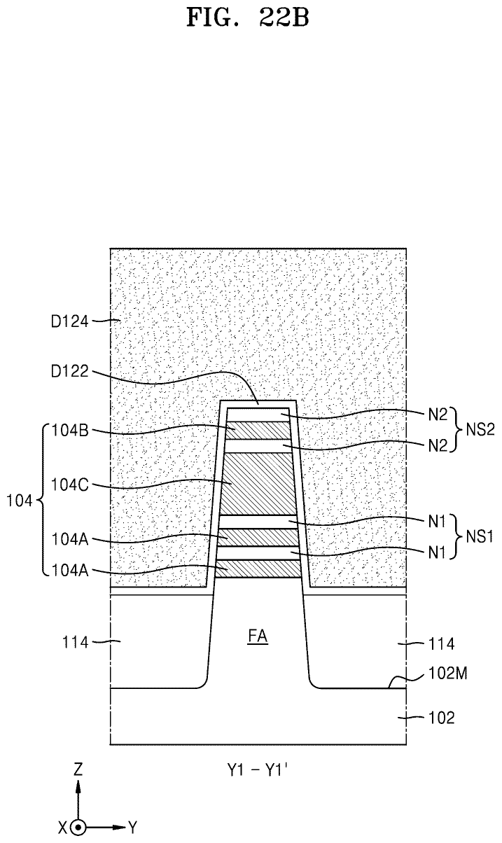

Referring to FIGS. 22A and 22B, an insulating liner 142 may be formed to cover the resultant structure of FIG. 21 in which the plurality of second source/drain regions SD2 are formed, and an inter-gate dielectric film 144 may be formed on the insulating liner 142. Thereafter, the insulating liner 142 and the inter-gate dielectric film 144 may be planarized to expose a top surface of the capping layer D126. Afterwards, the capping layer D126 may be removed to expose a top surface of the dummy gate layer D124, and the insulating liner 142 and the inter-gate dielectric film 144 may be partially removed such that a top surface of the inter-gate dielectric film 144 substantially becomes at the same level as the top surface of the dummy gate layer D124.

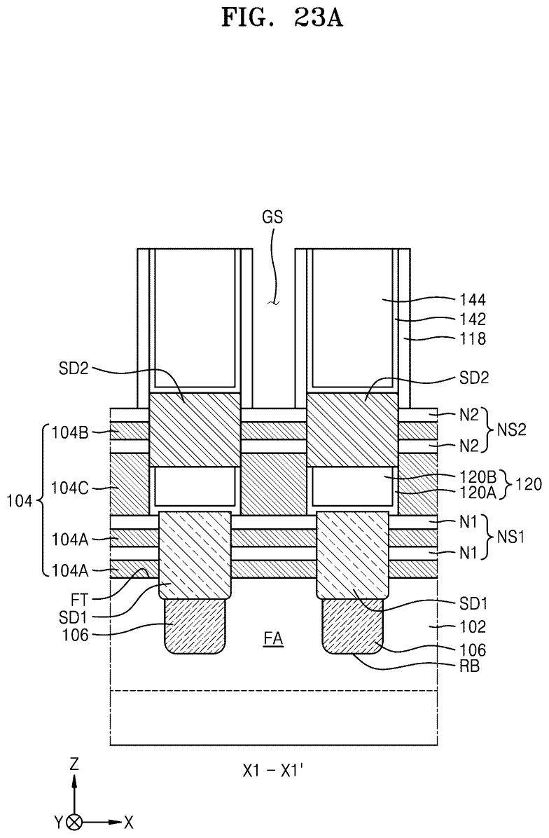

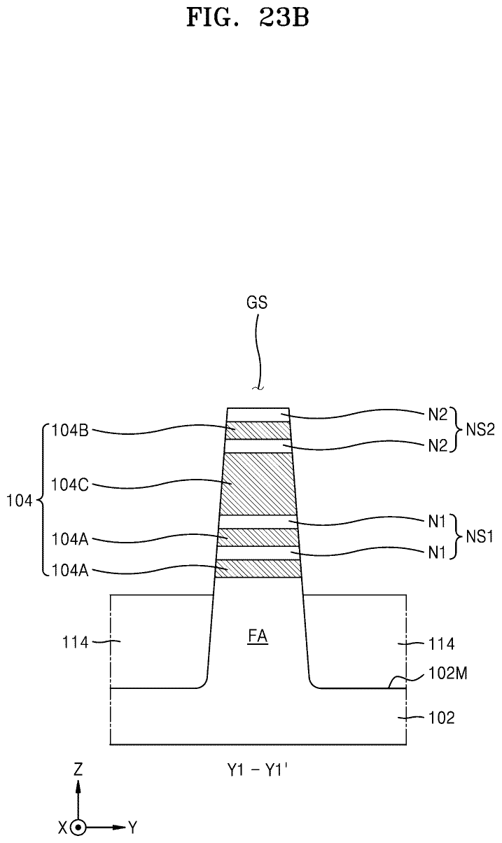

Referring to FIGS. 23A and 23B, the dummy gate layer D124 and the oxide film D122 located thereunder may be removed from the resultant structure of FIGS. 22A and 22B to provide a gate space GS. A plurality of first nanosheets N1 included in a first nanosheet stack NS1, a plurality of second nanosheets N2 included in a second nanosheet stack NS2, the plurality of sacrificial semiconductor layers 104, and the device isolation film 114 may be exposed through the gate space GS.

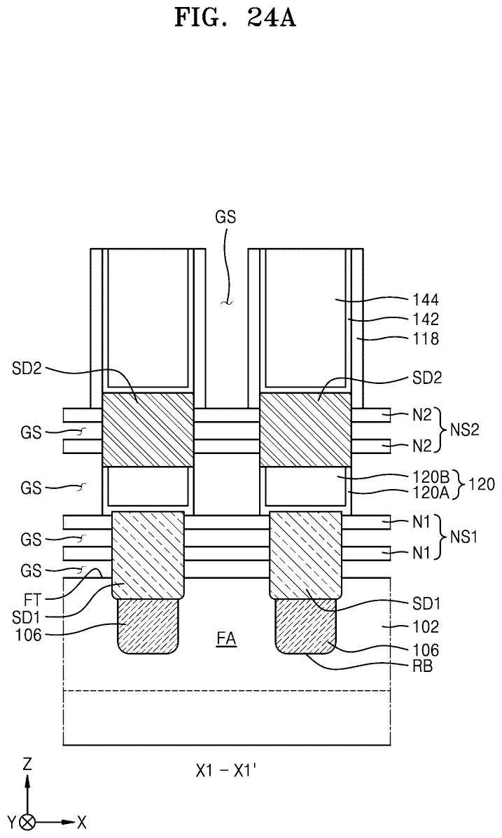

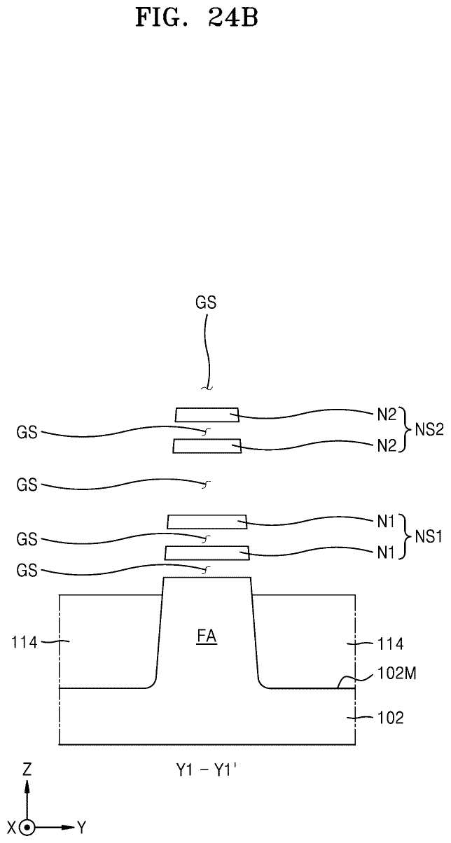

Referring to FIGS. 24A and 24B, the plurality of sacrificial semiconductor layers 104 remaining on the fin-type active region FA may be removed through the gate space GS from the resultant structure of FIGS. 23A and 23B, and thus, the gate space GS may extend to the fin top surface FT of the fin-type active region FA. After the gate space GS extends to the fin top surface FT of the fin-type active region FA, the plurality of first source/drain regions SD1 and the plurality of second source/drain regions SD2 may be exposed through the gate space GS.

In embodiments, to selectively remove the plurality of sacrificial semiconductor layers 104, etch selectivities of the plurality of first nanosheets N1 and the plurality of second nanosheets N2 with respect to the plurality of sacrificial semiconductor layers 104 may be used. A liquid or gaseous etchant may be used to selectively remove the plurality of sacrificial semiconductor layers 104. In embodiments, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

Referring to FIGS. 25A, 25B, and 25C, in the resultant structure of FIGS. 24A and 24B, a gate dielectric film 152 may be formed to cover respective exposed surfaces of the fin-type active region FA, the plurality of first nanosheets N1, the plurality of second nanosheets N2, the plurality of first source/drain regions SD1, the plurality of second source/drain regions SD2, and the device isolation film 114, which are exposed through the gate space GS. The gate dielectric film 152 may be formed by using an atomic layer deposition (ALD) process.

Next, a gate-forming conductive layer may be formed on the gate dielectric film 152 to fill the gate space (refer to GS in FIGS. 15A and 15B) and cover a top surface of the inter-gate dielectric film 144). The gate-forming conductive layer may include metal, metal nitride, metal carbide, or a combination thereof. The gate-forming conductive layer may be formed by using an ALD process, a chemical vapor deposition (CVD) process, or a combination thereof.

Thereafter, the gate-forming conductive layer may be partially removed from a top surface thereof to expose the top surface of the inter-gate dielectric film 144 and empty an upper portion of the gate space GS again, thereby forming a gate line GL. In this case, upper portions of the gate dielectric film 152 and the insulating spacer 118 may also be removed. Afterwards, a capping insulating pattern 164 filling the gate space GS may be formed on the gate line GL, the gate dielectric film 152, and the insulating spacer 118.

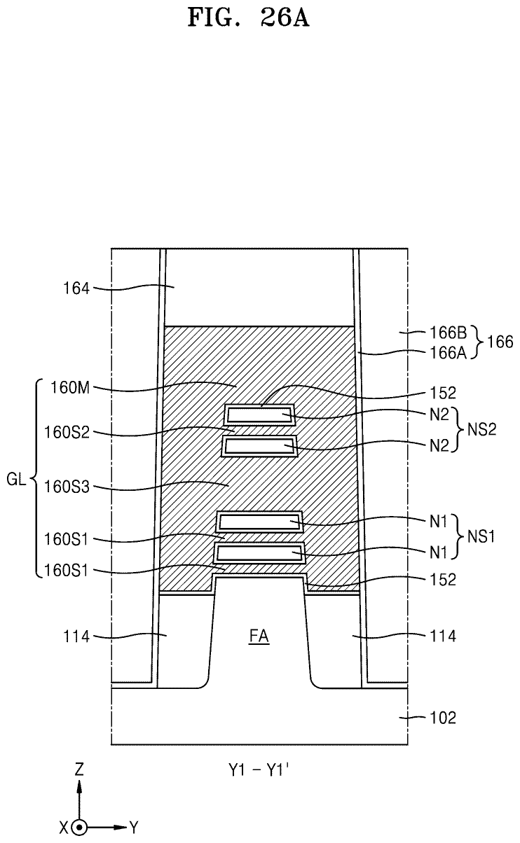

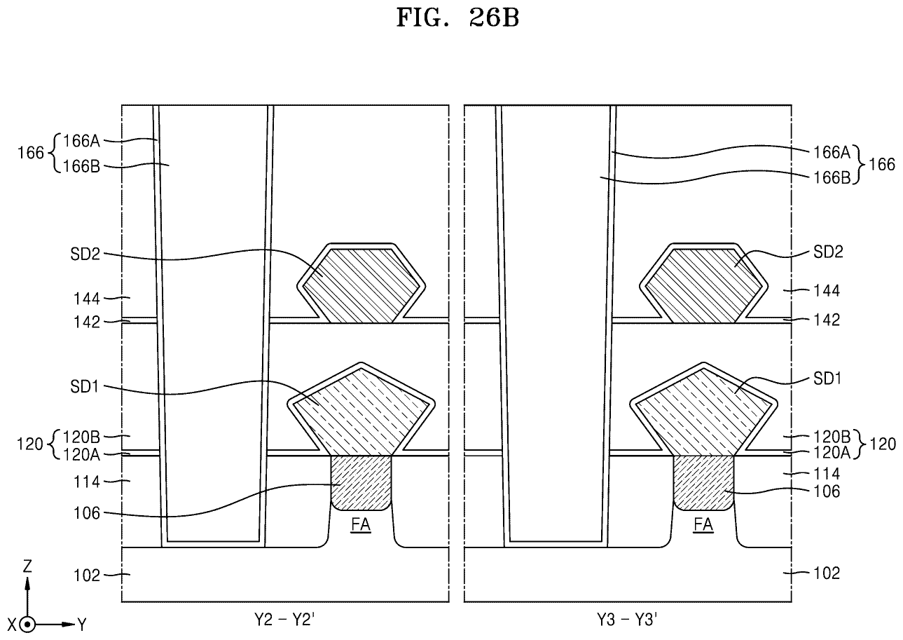

Referring to FIGS. 26A and 26B, a gate cut process of removing a portion of each of a plurality of gate lines GL may be performed on the resultant structure of FIGS. 25A, 25B, and 25C. To perform the gate cut process, in the resultant structure of FIGS. 25A, 25B, and 25C, a plurality of gate cut holes extending lengthwise in the first lateral direction (X direction) may be formed to pass through a plurality of capping insulating patterns 164, the plurality of gate lines GL, the inter-gate dielectric film 144, the insulating liner 142, the insulating pattern 120, and the device isolation film 114 in the vertical direction (Z direction), and then a plurality of gate cut insulating structures 166 may be formed to fill the plurality of gate cut holes. The plurality of gate cut insulating structures 166 may each include a barrier insulating film 166A) and a main insulating film 166B.

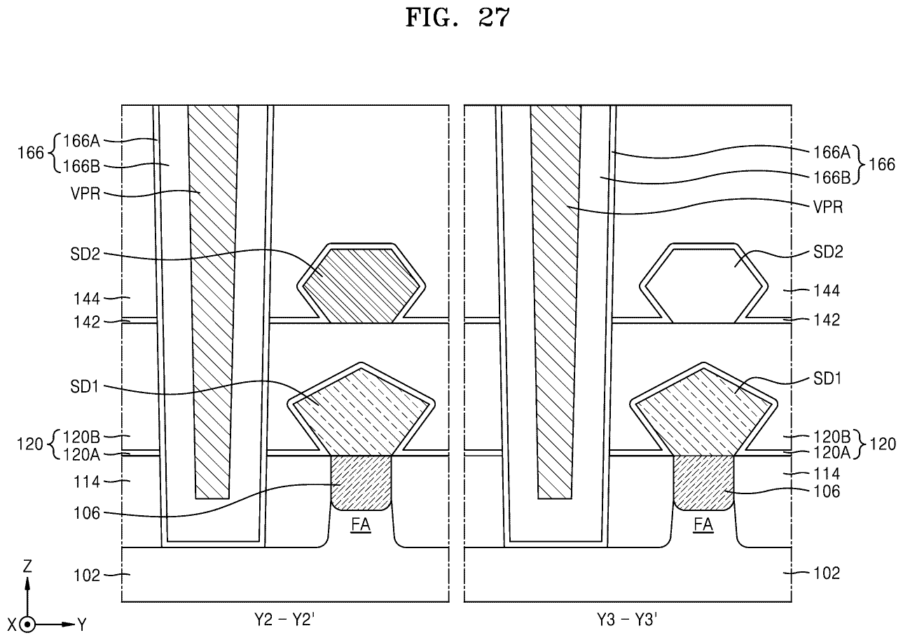

Referring to FIG. 27, a plurality of via power rails VPR may be formed to respectively pass through portions of the plurality of gate cut insulating structures 166 in the vertical direction (Z direction). A bottom surface of each of the plurality of via power rails VPR may be at a higher vertical level than a bottom surface of each of the plurality of gate cut insulating structures 166. Accordingly, the bottom surface of each of the plurality of via power rails VPR may be spaced apart in the vertical direction (Z direction) from the substrate 102 with a portion of the gate cut insulating structure 166 therebetween.

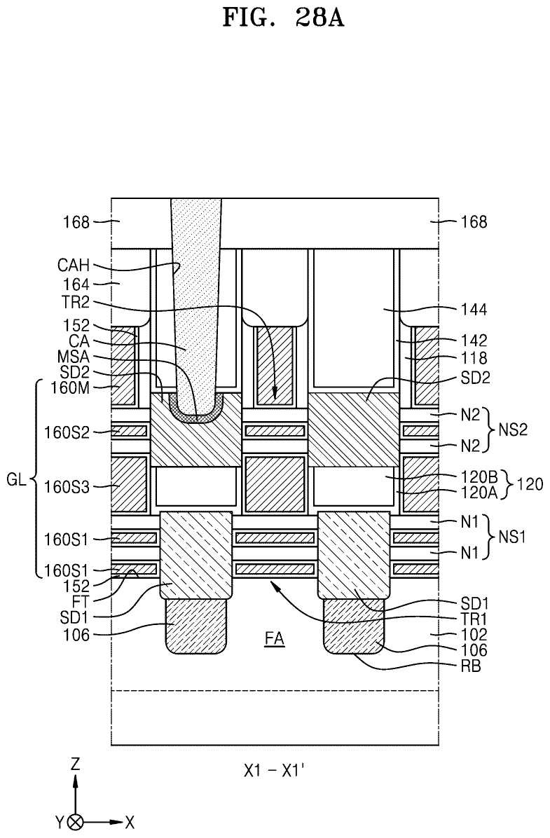

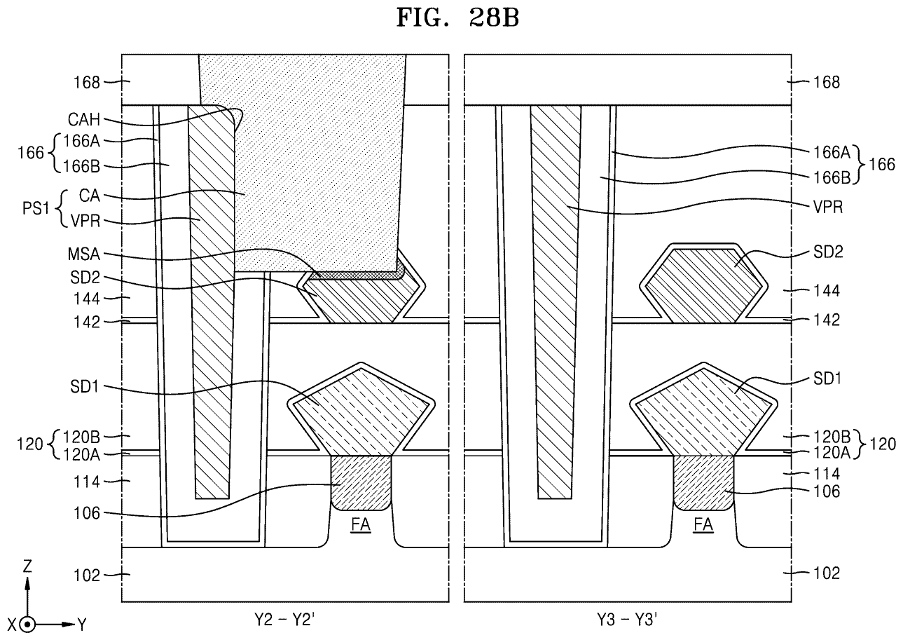

Referring to FIGS. 28A and 28B, an upper insulating film 168 may be formed to cover a top surface of the resultant structure on which the processes described with reference to FIG. 27 have been performed, and at least one contact hole CAH exposing at least one second source/drain region SD2 selected from the plurality of second source/drain regions SD2 may be formed to pass through the upper insulating film 168, the inter-gate dielectric film 144, and the insulating liner 142 in the vertical direction (Z direction) from a top surface of the upper insulating film 168. During the formation of the contact hole CAH, a partial region of the second source/drain region SD2 may be etched, and the contact hole CAH may pass through a portion of the second source/drain region SD2 in the vertical direction (Z direction). To form a front-side contact CA to be in contact with the via power rail VPR as shown in FIG. 28B, the contact hole CAH exposing the second source/drain region SD2 may be formed to expose a portion of the via power rail VPR through the contact hole CAH. During an etching process of forming the contact hole CAH, the portion of the via power rail VPR, which is exposed through the contact hole CAH, may be consumed.

Then, a front-side metal silicide film MSA may be formed to cover a front-side surface of the second source/drain region SD2 exposed through the contact hole CAH, and the front-side contact CA may be formed to fill the contact hole CAH on the front-side metal silicide film MSA.

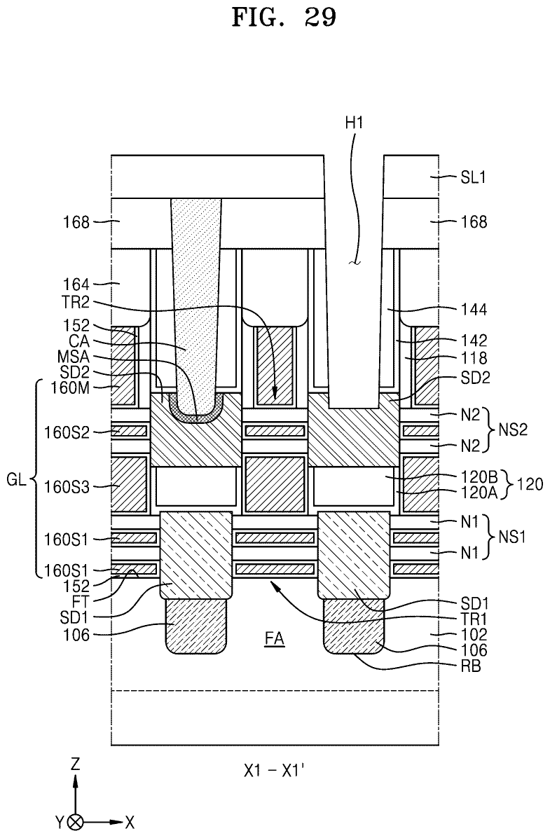

Referring to FIG. 29, a sacrificial mask pattern SL1 may be formed on the resultant structure of FIGS. 28A and 28B. The sacrificial mask pattern SL1 may include a silicon oxide film, a silicon nitride film, a photoresist pattern, or a combination thereof. Thereafter, by using the sacrificial mask pattern SL1 as an etch mask, a first through hole H1 exposing another selected one of the plurality of second source/drain regions SD2 may be formed to pass through the upper insulating film 168, the inter-gate dielectric film 144, and the insulating liner 142 in the vertical direction (Z direction) from the top surface of the upper insulating film 168. During the formation of the first through hole H1, a partial region of the second source/drain region SD2 may be etched, and the first through hole H1 may pass through a portion of the second source/drain region SD2 in the vertical direction (Z direction).

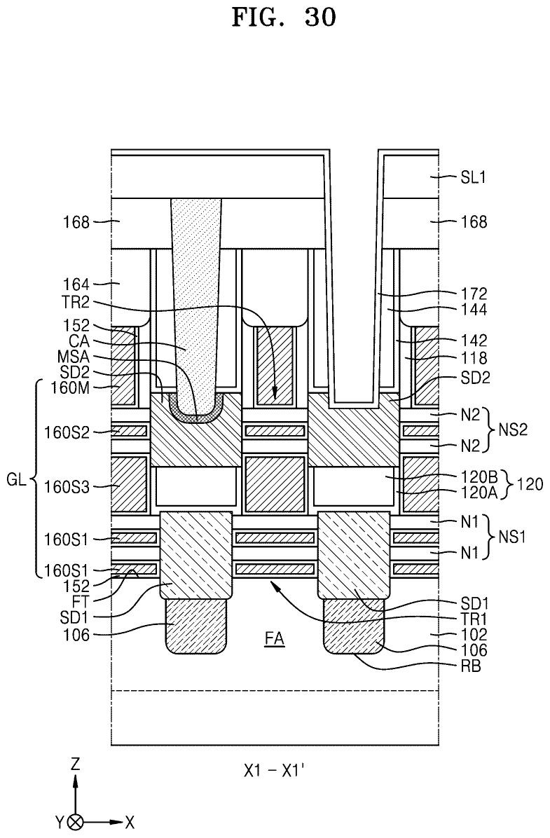

Referring to FIG. 30, an insulating liner 172 conformally covering inner surfaces of the first through hole H1 may be formed on the resultant structure of FIG. 29.

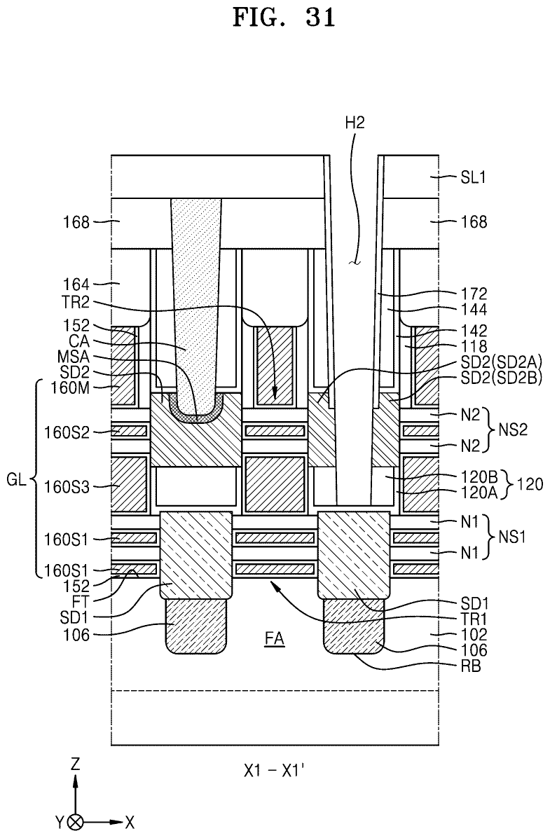

Referring to FIG. 31, the second source/drain region SD2 and the second insulating pattern 120B located thereunder may be etched through the first through hole H1 by using the insulating liner 172 and the sacrificial mask pattern SL1 as etch masks, and thus, a second through hole H2 may be formed. The first insulating pattern 120A may be exposed at a bottom surface of the second through hole H2, and the insulating liner 172, the second source/drain region SD2, and the second insulating pattern 120B may be exposed at an inner sidewall of the second through hole H2. Because the second through hole H2 is formed to pass through the second source/drain region SD2 in the vertical direction (Z direction), the second source/drain region SD2 may be divided into a first local portion SD2A and a second local portion SD2B.

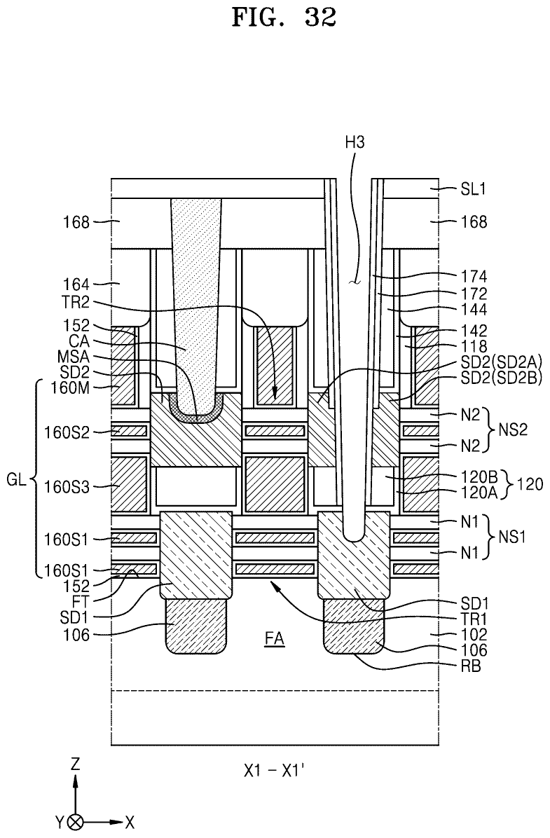

Referring to FIG. 32, a capping liner 174 covering the inner sidewall of the second through hole H2 may be formed on the resultant structure of FIG. 31. The capping liner 174 may include a material having an etch selectivity with respect to a constituent material of the insulating liner 172. For example, the capping liner 174 may be selected from a silicon nitride film, a SiCN film, a SiON film, and a SiOCN film, without being limited thereto.

Afterwards, a portion of each of the insulating liner 142 and the first source/drain region SD1 located thereunder may be etched through the second through hole H2 by using the capping liner 174 and the sacrificial mask pattern SL1 as etch masks. Thus, a third through hole H3 may be formed to expose the first source/drain region SD1 at a bottom surface thereof. The third through hole H3 may include a portion passing through an upper portion of the first source/drain region SD1 in the vertical direction (Z direction). During an etching process of forming the third through hole H3, the sacrificial mask pattern SL1 may be partially consumed.

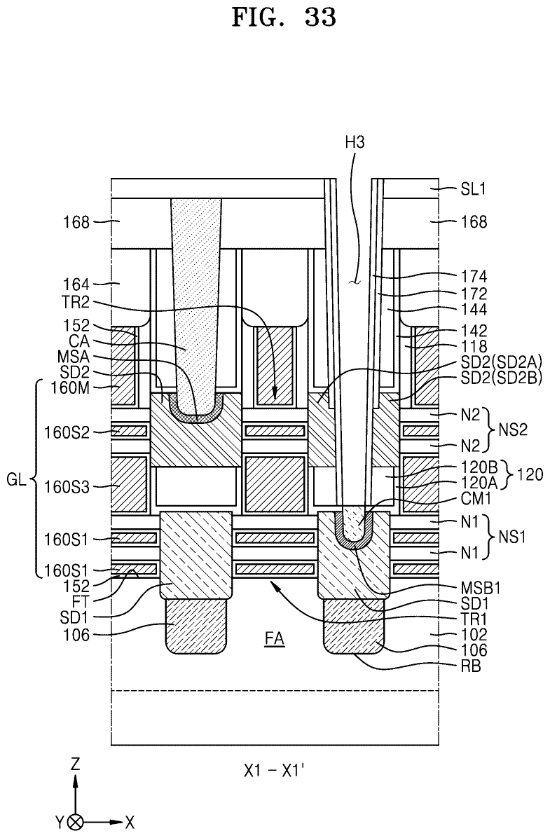

Referring to FIG. 33, in the resultant structure of FIG. 32, a first metal silicide film MSB1 may be formed to contact the first source/drain region SD1 exposed through the third through hole H3, and a lower contact plug CM1 may be formed on the first metal silicide film MSB1 to fill a portion of the third through hole H3, which is surrounded by the first source/drain region SD1.

In an example of the process of forming the first metal silicide film MSB1 and the lower contact plug CM1, a metal film filling the third through hole H3 may be formed and annealed, and a portion of the metal film may be removed by an etchback process. The portion of the metal film may react with a portion of the first source/drain region SD1 due to the annealing process, and thus, the first metal silicide film MSB1 may be formed to cover a surface of the first source/drain region SD1, which faces the metal film. A portion of the metal film, which remains inside the third through hole H3 surrounded by the first source/drain region SD1, may be left as the lower contact plug CM1. After the lower contact plug CM1 is formed, a top surface of the lower contact plug CM1 may be exposed at the bottom surface of the third through hole H3, and the capping liner 174 may be exposed at a sidewall of the third through hole H3.

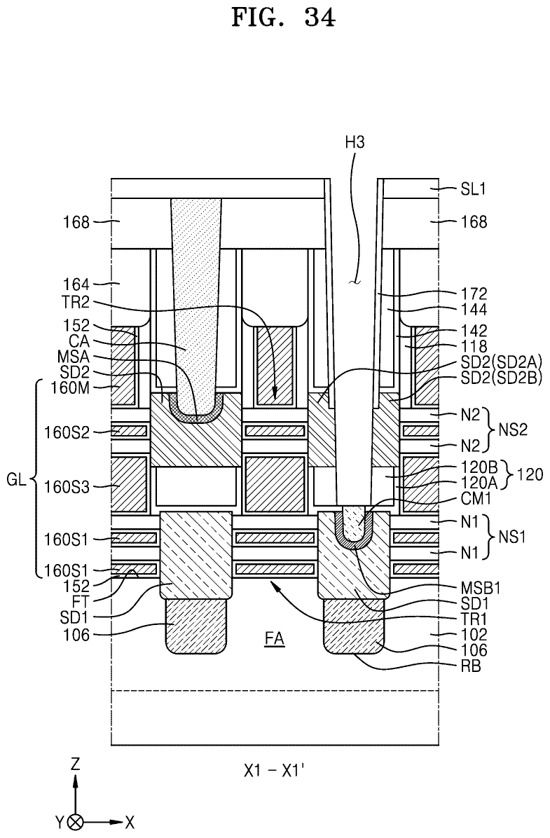

Referring to FIG. 34, the capping liner 174 may be removed from the resultant structure of FIG. 33, and thus, the first local portion SD2A and the second local portion SD2B of the second source/drain region SD2 may be exposed at the sidewall of the third through hole H3.

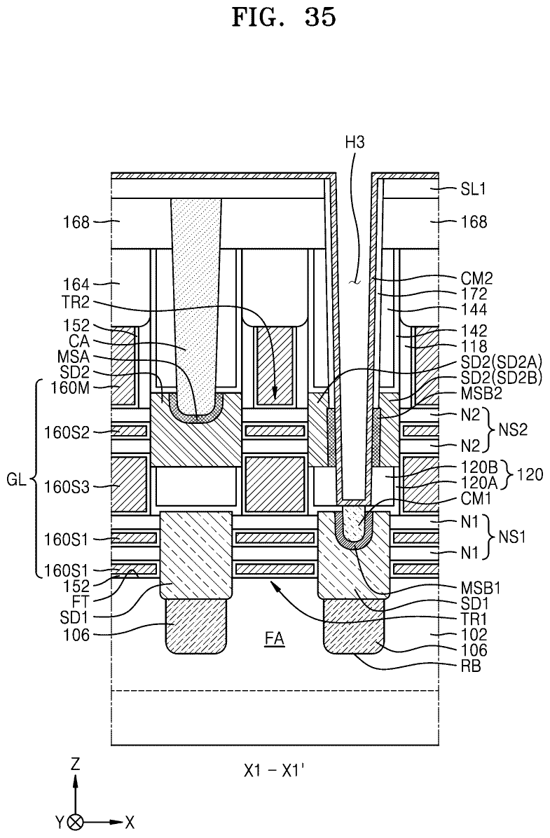

Referring to FIG. 35, in the resultant structure of FIG. 34, a conductive liner may be formed to conformally cover inner surfaces of the third through hole H3, and then annealed to form a conductive contact liner CM2, which includes the remaining portion of the conductive liner. The conductive liner may react with a portion of the second source/drain region SD2 due to the annealing process, and thus, a second metal silicide film MSB2 may be formed between the second source/drain region SD2 and the conductive contact liner CM2.

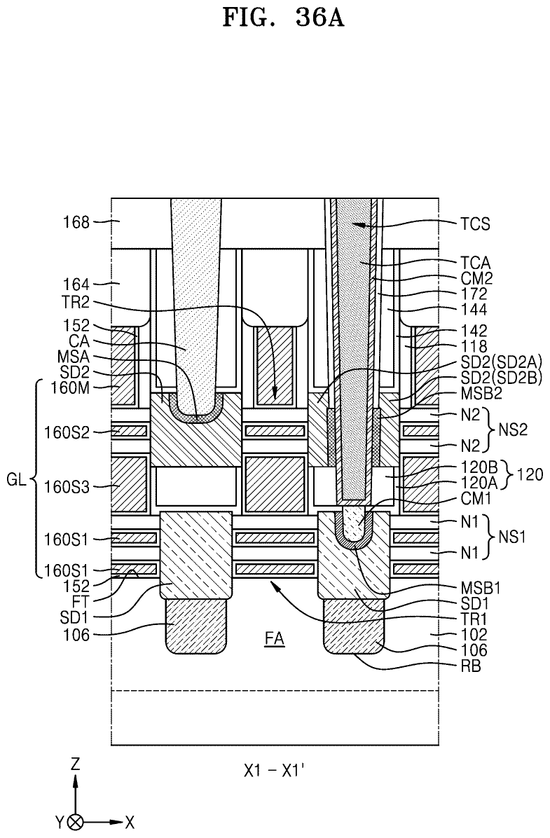

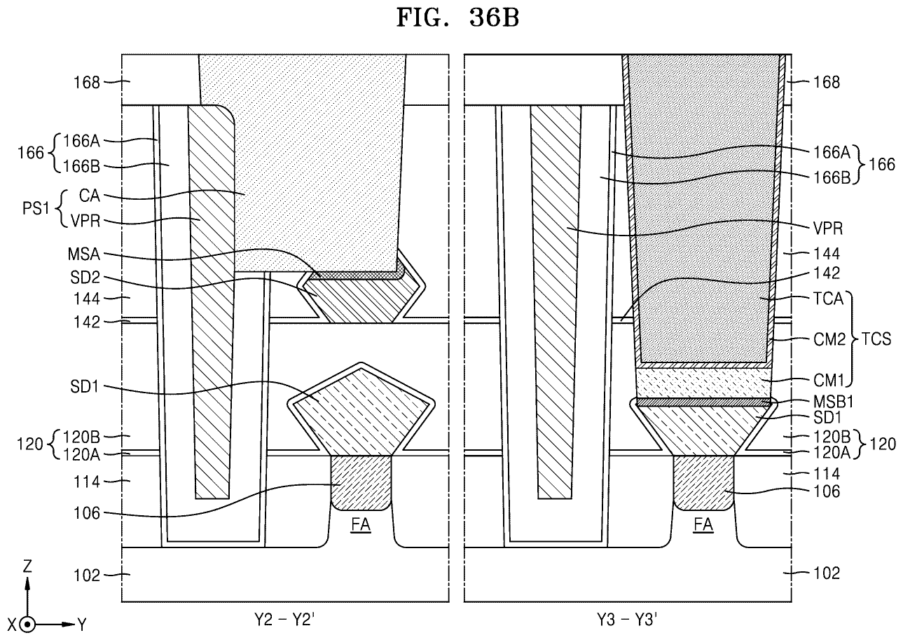

Referring to FIGS. 36A and 36B, in the resultant structure on which the process described with reference to FIG. 35 has been performed, an upper contact plug TCA filling the third through hole H3 may be formed on the conductive contact liner CM2, and a planarization process of removing unnecessary films on the upper insulating film 168 may be performed to expose a top surface of the upper insulating film 168. A lower contact plug CM21, the conductive contact liner CM2, and the upper contact plug TCA may constitute a through contact structure TCS2.

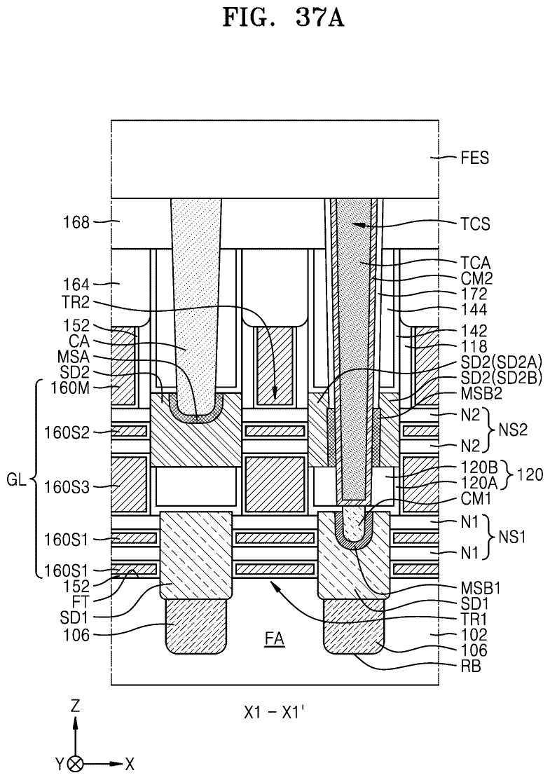

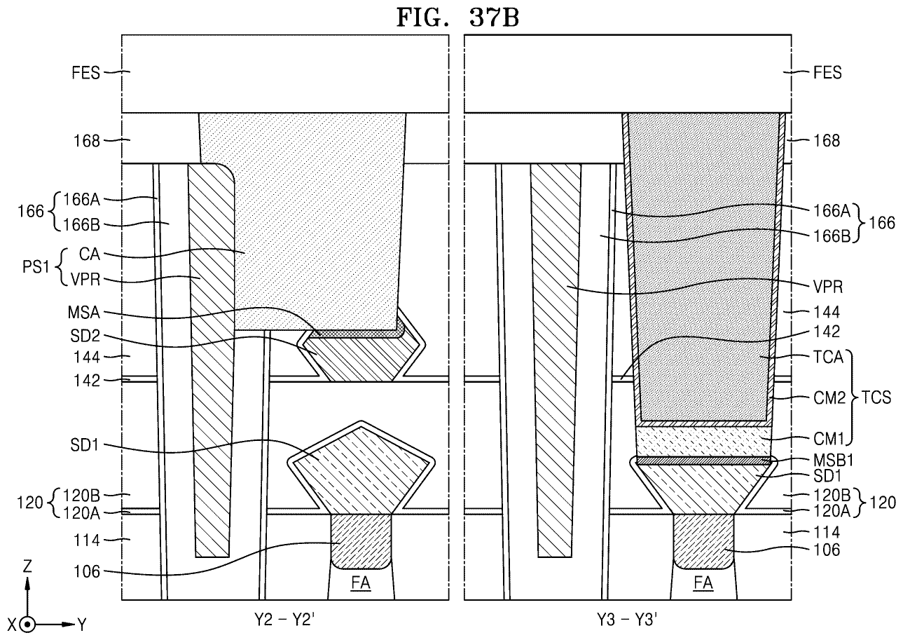

Referring to FIGS. 37A and 37B, in the resultant structure of FIGS. 36A and 36B, a front-side wiring structure FES may be formed on the top surface of each of the front-side contact CA, the through contact structure TCS2, and the upper insulating film 168.

Thereafter, the substrate 102 may be removed from a back side of a structure including the front-side wiring structure FES to expose a plurality of fin-type active regions FA and the device isolation film 114, and respective portions of the plurality of fin-type active regions FA and the device isolation film 114, which are exposed, may be further removed. Thus, a thickness of each of the plurality of fin-type active regions FA and the device isolation film 114 in the vertical direction (Z direction) may be reduced.

In embodiments, the process of removing the substrate 102 and the process of removing the portion of each of the plurality of fin-type active regions FA and the device isolation film 114 may be performed by using at least one process selected from a mechanical grinding process, a chemical mechanical polishing (CMP) process, a wet etching process, and a combination thereof.

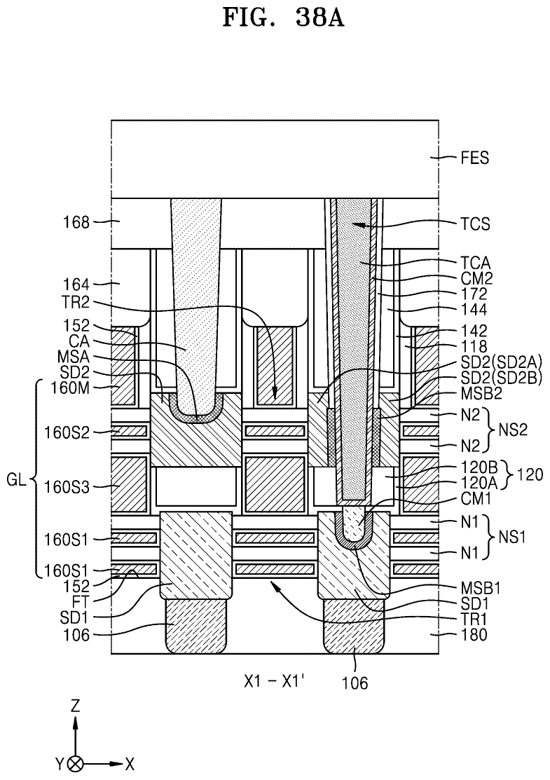

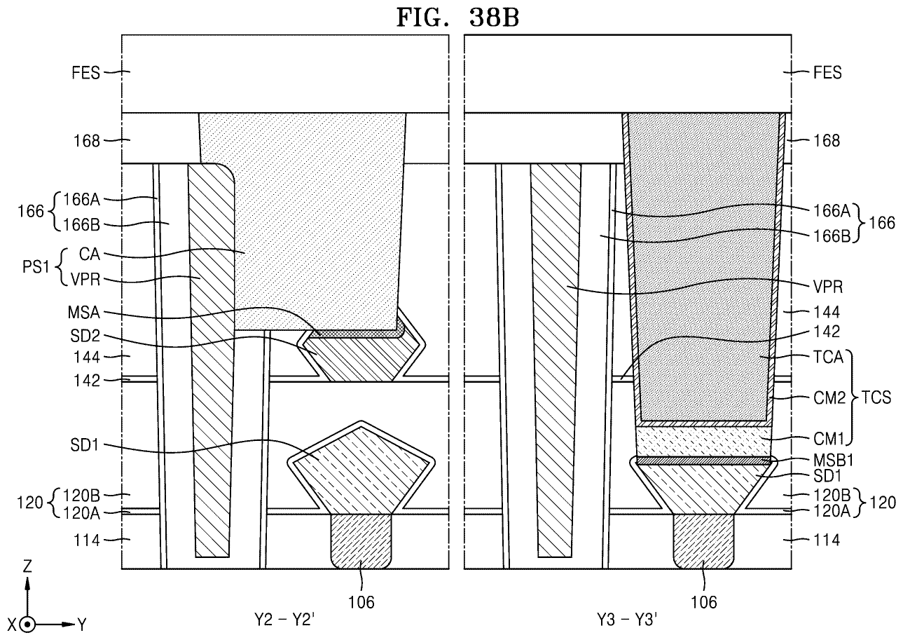

Referring to FIGS. 38A and 38B, in the resultant structure of FIGS. 37A and 37B, a thickness in the vertical direction (Z direction) of each of the plurality of fin-type active regions FA and the device isolation film 114 may be further reduced to expose the plurality of place holders 106. Afterwards, the plurality of fin-type active regions FA, which remain in the obtained resultant structure, may be replaced by a first back-side insulating film 180. To this end, the plurality of fin-type active regions FA may be removed to provide a separation space between two adjacent ones of the plurality of place holders 106, and the separation space may be filled by the first back-side insulating film 180.

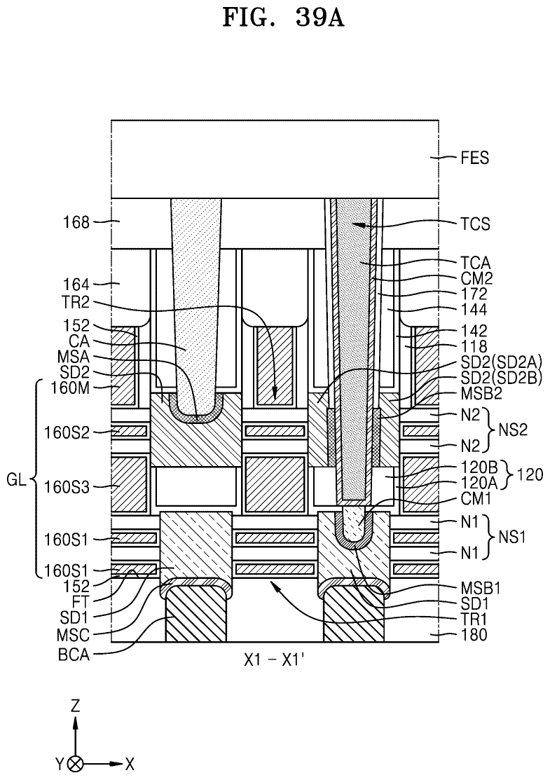

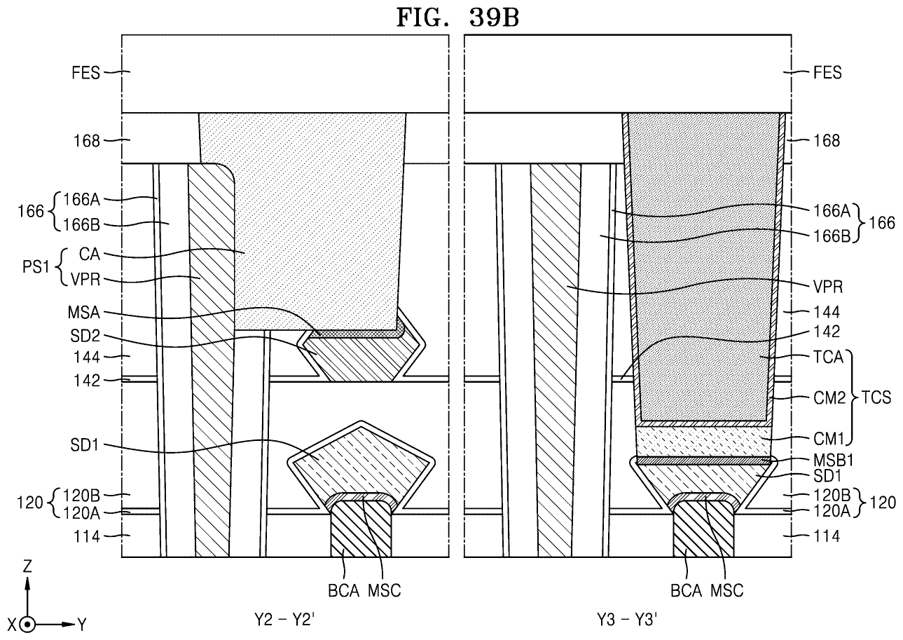

Referring to FIGS. 39A and 39B, the plurality of place holders 106 may be removed from the resultant structure of FIGS. 38A and 38B to expose a back-side surface of each of the plurality of first source/drain regions SD1. During the removal of the plurality of place holders 106, a portion of each of the plurality of first source/drain regions SD1, which are exposed, may be removed, and thus, each of the plurality of first source/drain regions SD1 may have a recessed back-side surface. Thereafter, a back-side metal silicide film MSC may be formed to cover the recessed back-side surface of each of the plurality of first source/drain regions SD1, and a back-side contact BCA may be formed to fill a space defined by the back-side metal silicide film MSC and the device isolation film 114 and the first back-side insulating film 180, which are adjacent to the back-side metal silicide film MSC. The back-side metal silicide film MSC and the back-side contact BCA may be spaced apart in the vertical direction (Z direction) from the through contact structure TCS with the first source/drain region SD1 and the first metal silicide film MSB1 therebetween.

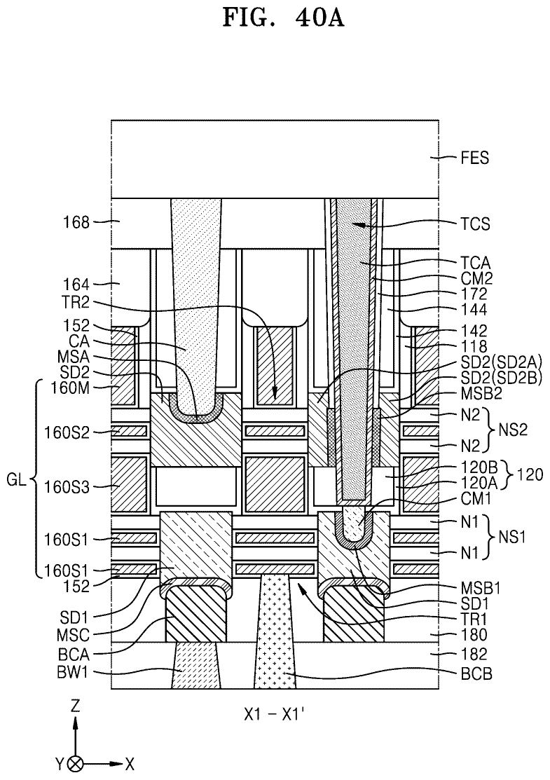

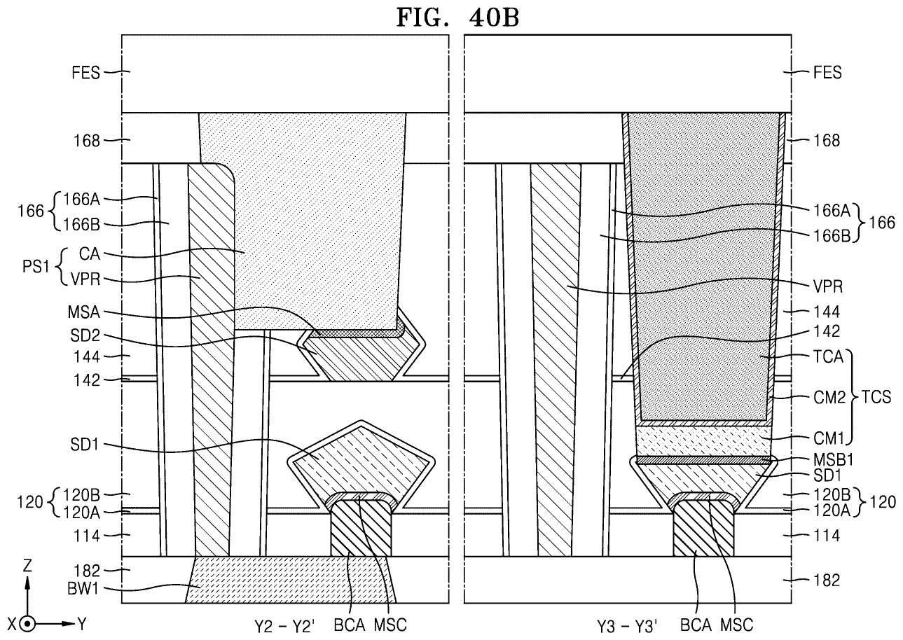

Referring to FIGS. 40A and 40B, in the resultant structure of FIGS. 39A and 39B, a second back-side insulating film 182 may be formed to cover a plurality of back-side contacts BCA, the device isolation film 114, and the first back-side insulating film 180, and a back-side wiring layer BW1 may be formed to pass through the second back-side insulating film 182 and contact the back-side contact BCA, the second back-side insulating film 182, and the first back-side insulating film 180. A back-side gate contact BCB may be formed to pass through the gate dielectric film 152 and contact the gate line GL. Thus, the IC device 100 shown in FIGS. 1A, 1B, and 2A to 2F may be manufactured.

Although the methods of manufacturing the IC device 100 shown in FIGS. 1A, 1B, and 2A to 2F have been described with reference to FIGS. 10A, 10B, 11A, 11B, 12 to 21, 22A, 22B, 23A, 23B, 24A, 24B, 25A, 25B, 25C, 26A, 26B, 27, 28A, 28B, 29 to 35, 36A, 36B, 37A, 37B, 38A, 38B, 39A, 39B, 40A and 40B, it will be understood that the IC devices 200, 300, 400, 500, 600, 700, and 800 shown in FIGS. 3 to 7, 8A, 8B, 9A, 9B and 9C and IC devices having various structures may be manufactured by making various modifications and changes to the processes described with reference to FIGS. 10A, 10B, 11A, 11B, 12 to 21, 22A, 22B, 23A, 23B, 24A, 24B, 25A, 25B, 25C, 26A, 26B, 27, 28A, 28B, 29 to 35, 36A, 36B, 37A, 37B, 38A, 38B, 39A, 39B, 40A and 40B within the scope of the disclosed concepts.

While the disclosed concepts have been particularly shown and described with reference to embodiments thereof, it will be understood that various changes in form and details may be made therein without departing from the spirit and scope of the following claims.

What is claimed is:

1. An integrated circuit device comprising:
a first source/drain region comprising a first-conductivity-type semiconductor material;
a second source/drain region overlapping the first source/drain region in a vertical direction and spaced apart from the first source/drain region in the vertical direction, and the second source/drain region comprising a second-conductivity-type semiconductor material;
a through contact structure passing through the second source/drain region in the vertical direction, and connected to each of the first source/drain region and the second source/drain region;
a first metal silicide film between the first source/drain region and the through contact structure; and
a second metal silicide film between the second source/drain region and the through contact structure,
wherein the first metal silicide film and the second metal silicide film comprise different materials from one another.

2. The integrated circuit device of claim 1, further comprising:
a first nanosheet in contact with the first source/drain region;
a second nanosheet overlapping the first nanosheet in the vertical direction and spaced apart from the first nanosheet in the vertical direction, the second nanosheet being in contact with the second source/drain region; and
a gate line surrounding the first nanosheet and the second nanosheet and spaced apart from each of the first source/drain region and the second source/drain region in a first lateral direction,
wherein the through contact structure has a first portion having a first width in the first lateral direction and a second portion having a second width in the first lateral direction, the first width being less than the second width, a distance between the first portion and the first source/drain region being less than a distance between the second portion and the first source/drain region.

3. The integrated circuit device of claim 1, wherein the through contact structure comprises:
an upper contact plug passing through the second source/drain region in the vertical direction, the upper contact plug having a sidewall facing the second source/drain region in a first lateral direction and a bottom surface facing the first source/drain region in the vertical direction, and the upper contact plug being spaced apart from each of the first source/drain region and the second source/drain region;
a conductive contact liner between the second source/drain region and the upper contact plug, the conductive contact liner surrounding the sidewall and the bottom surface of the upper contact plug; and
a lower contact plug spaced apart in the vertical direction from the upper contact plug with the conductive contact liner therebetween, the lower contact plug comprising a portion surrounded by the first source/drain region.

4. The integrated circuit device of claim 3, wherein the first metal silicide film is between the lower contact plug of the through contact structure and the first source/drain region and is in contact with each of the lower contact plug and the first source/drain region, and
the second metal silicide film is between the conductive contact liner and the second source/drain region and is in contact with each of the conductive contact liner and the second source/drain region.

5. The integrated circuit device of claim 1, further comprising:
a back-side contact spaced apart in the vertical direction from the through contact structure with the first source/drain region therebetween; and
a back-side metal silicide film between the back-side contact and the first source/drain region, the back-side metal silicide film being in contact with each of the back-side contact and the first source/drain region.

6. The integrated circuit device of claim 1, further comprising:
a gate line adjacent to each of the first source/drain region and the second source/drain region in a first lateral direction;
a gate cut insulating structure defining a length of the gate line in a second lateral direction and extending in the first lateral direction, wherein the second lateral direction is substantially perpendicular to the first lateral direction; and
a via power rail passing through the gate cut insulating structure in the vertical direction.

7. The integrated circuit device of claim 1, further comprising:
a gate line adjacent to each of the first source/drain region and the second source/drain region in a first lateral direction;
a gate cut insulating structure defining a length of the gate line and extending in a second lateral direction, wherein the second lateral direction is substantially perpendicular to the first lateral direction;
a via power rail passing through the gate cut insulating structure in the vertical direction; and
a back-side contact spaced apart in the vertical direction from the through contact structure with the first source/drain region therebetween.

8. The integrated circuit device of claim 1, further comprising:
a back-side contact; and
a back-side metal silicide film between the back-side contact and the first source/drain region, the back-side metal silicide film being in contact with each of the back-side contact and the first source/drain region,
wherein the through contact structure comprises:
an upper contact plug passing through the second source/drain region in the vertical direction;
a conductive contact liner between the second source/drain region and the upper contact plug, the conductive contact liner surrounding a sidewall and a bottom surface of the upper contact plug; and
a lower contact plug spaced apart in the vertical direction from the upper contact plug with the conductive contact liner therebetween, the lower contact plug comprising a portion surrounded by the first source/drain region,
wherein the back-side contact and the lower contact plug overlap one another in the vertical direction and are in contact with one another.

9. The integrated circuit device of claim 1, wherein the through contact structure comprises:
an upper contact plug passing through the second source/drain region in the vertical direction;
a conductive contact liner between the second source/drain region and the upper contact plug, the conductive contact liner surrounding a sidewall and a bottom surface of the upper contact plug; and
a lower contact plug spaced apart in the vertical direction from the upper contact plug with the conductive contact liner therebetween, the lower contact plug comprising a portion surrounded by the first source/drain region,
wherein the lower contact plug is located inside the through hole, and the through hole passes through the first source/drain region from a front-side surface of the first source/drain region to a back-side surface of the first source/drain region in the vertical direction.

10. The integrated circuit device of claim 1, wherein:
the second source/drain region comprises a first local portion and a second local portion, the first and second local portions being spaced apart in a first lateral direction from one another with the through contact structure therebetween, and
the second metal silicide film comprises a first portion in contact with the first local portion of the second source/drain region and a second portion in contact with the second local portion of the second source/drain region.

11. The integrated circuit device of claim 1, wherein the through contact structure comprises:
an upper contact plug passing through the second source/drain region in the vertical direction;
a conductive contact liner between the second source/drain region and the upper contact plug, the conductive contact liner surrounding a sidewall and a bottom surface of the upper contact plug; and
a lower contact plug spaced apart in the vertical direction from the upper contact plug with the conductive contact liner therebetween, the lower contact plug passing through at least a portion of the first source/drain region in the vertical direction,
wherein the upper contact plug, the conductive contact liner, and the lower contact plug comprise different metals from one another.

12. An integrated circuit device comprising:
at least one first nanosheet and at least one second nanosheet overlapping one another in a vertical direction and spaced apart from one another in the vertical direction;
a pair of first source/drain regions spaced apart in a first lateral direction from one another with the at least one first nanosheet therebetween, the pair of first source/drain regions being each in contact with the at least one first nanosheet and comprising a first-conductivity-type semiconductor material;
a pair of second source/drain regions spaced apart in the first lateral direction from one another with the at least one second nanosheet therebetween, the pair of second source/drain regions being each in contact with the at least one second nanosheet and spaced apart from the first source/drain region in the vertical direction, and the pair of second source/drain regions comprising a second-conductivity-type semiconductor material;
a gate line between the pair of first source/drain regions and between the pair of second source/drain regions, the gate line surrounding the at least one first nanosheet and the at least one second nanosheet;
a through contact structure passing through a first one of the pair of second source/drain regions in the vertical direction;
a first metal silicide film between a first one of the pair of first source/drain regions and the through contact structure; and
a second metal silicide film between the first one of the pair of second source/drain regions and the through contact structure,
wherein the first metal silicide film and the second metal silicide film comprise different materials from one another.

13. The integrated circuit device of claim 12, further comprising:
a front-side contact; and
a front-side metal silicide film between a front-side surface of a second one of the pair of second source/drain regions and the front-side contact,
wherein the second metal silicide film and the front-side metal silicide film comprise the same material.

14. The integrated circuit device of claim 12, wherein the through contact structure comprises:
an upper contact plug passing through the first one of the pair of second source/drain regions in the vertical direction, the upper contact plug having a sidewall and a bottom surface, wherein the sidewall faces the first one of the pair of second source/drain regions in the first lateral direction, the bottom surface faces the first one of the pair of first source/drain regions in the vertical direction, and the upper contact plug is spaced apart from each of the first one of the pair of first source/drain regions and the first one of the pair of second source/drain regions;
a conductive contact liner between the first one of the pair of second source/drain regions and the upper contact plug, the conductive contact liner surrounding the sidewall and the bottom surface of the upper contact plug; and
a lower contact plug spaced apart in the vertical direction from the upper contact plug with the conductive contact liner therebetween, the lower contact plug comprising a portion surrounded by the first one of the pair of first source/drain regions.

15. The integrated circuit device of claim 12, further comprising:
a pair of back-side contacts disposed below the pair of first source/drain regions; a gate cut insulating structure defining a length of the gate line in a second lateral direction and extending in the first lateral direction, wherein the second lateral direction is substantially perpendicular to the first lateral direction; and
a plurality of via power rails passing through the gate cut insulating structure in the vertical direction.

16. The integrated circuit device of claim 12, further comprising:
a front-side contact disposed on a second one of the pair of second source/drain regions;
a gate cut insulating structure defining a length of the gate line in a second lateral direction and extending in the first lateral direction, wherein the second lateral direction is substantially perpendicular to the first lateral direction; and
a plurality of via power rails passing through the gate cut insulating structure in the vertical direction.

17. The integrated circuit device of claim 12, wherein:
the first one of the pair of second source/drain regions comprises a first local portion and a second local portion, the first and second local portions being spaced apart in the first lateral direction from one another with the through contact structure therebetween, and
the second metal silicide film comprises a first portion in contact with the first local portion of the first one of the pair of second source/drain regions and a second portion in contact with the second local portion of the first one of the pair of second source/drain regions.

18. The integrated circuit device of claim 12, wherein the through contact structure comprises:
an upper contact plug passing through the first one of the pair of second source/drain regions in the vertical direction;
a conductive contact liner between the first one of the pair of second source/drain regions and the upper contact plug, the conductive contact liner surrounding a sidewall and a bottom surface of the upper contact plug; and
a lower contact plug spaced apart in the vertical direction from the upper contact plug with the conductive contact liner therebetween, the lower contact plug passing through at least a portion of the first one of the pair of first source/drain regions in the vertical direction,
wherein the upper contact plug, the conductive contact liner, and the lower contact plug comprise different metals from one another.

19. An integrated circuit device comprising:
a first source/drain region comprising a p-type semiconductor material;
a second source/drain region overlapping the first source/drain region in a vertical direction and spaced apart from the first source/drain region in the vertical direction, the second source/drain region comprising an n-type semiconductor material;
a through contact structure passing through the second source/drain region in the vertical direction;
a first metal silicide film between the first source/drain region and the through contact structure; and
a second metal silicide film between the second source/drain region and the through contact structure, the second metal silicide film comprising a material different from a material that the first metal silicide film includes,
wherein the through contact structure comprises:
an upper contact plug passing through the second source/drain region in the vertical direction;
a conductive contact liner between the second source/drain region and the upper contact plug, the conductive contact liner surrounding a sidewall and a bottom surface of the upper contact plug; and
a lower contact plug spaced apart in the vertical direction from the upper contact plug with the conductive contact liner therebetween, the lower contact plug comprising a portion surrounded by the first source/drain region,
wherein the upper contact plug, the conductive contact liner, and the lower contact plug comprise different metals from one another, the metals being selected from molybdenum (Mo), zirconium (Zr), tungsten (W), copper (Cu), cobalt (Co), ruthenium (Ru), manganese (Mn), titanium (Ti), tantalum (Ta), and aluminum (Al).

20. The integrated circuit device of claim 19, further comprising:
a first nanosheet in contact with the first source/drain region;
a second nanosheet overlapping the first nanosheet in the vertical direction and spaced apart from the first nanosheet in the vertical direction, the second nanosheet being in contact with the second source/drain region;
a gate line surrounding the first nanosheet and the second nanosheet and spaced apart from each of the first source/drain region and the second source/drain region in a first lateral direction;
a gate cut insulating structure defining a length of the gate line in a second lateral direction and extending in the first lateral direction, wherein the second lateral direction is substantially perpendicular to the first lateral direction;
a plurality of via power rails passing through the gate cut insulating structure in the vertical direction; and
a back-side contact connected to a back-side surface of the first source/drain region.
